(19) United States
(12) Patent Application Publication
(10) Pub. No.: US 2015/0221364 A1
(43) Pub. Date: Aug. 6, 2015

(54) SEMICONDUCTOR DEVICE, STORAGE DEVICE, AND CONTROL METHOD OF STORAGE DEVICE

(71) Applicant: Semiconductor Technology Academic Research Center, Yokohama-shi (JP)

(72) Inventor: Toshiro HIRAMOTO, Tokyo (JP)

(21) Appl. No.: 14/608,674

(22) Filed: Jan. 29, 2015

(30) Foreign Application Priority Data
Feb. 6, 2014 (JP) 2014-021398

(51) Int. Cl. G11C 11/419; G11C 5/06

(52) U.S. Cl. CPC G11C 11/419; G11C 5/06

(57) ABSTRACT

A semiconductor device includes a plurality of storage elements each having a plurality of MOS transistors forming a latch circuit, a stored data setting unit configured to write inverted data of nonvolatile data that is read when each of the plurality of storage elements functions as a nonvolatile memory cell to each of the plurality of storage elements, and a voltage application unit configured to store the nonvolatile data in each of the plurality of storage elements by applying a predetermined high voltage higher than a power source voltage applied during normal latch operation to each of the latch circuits.

### CROSS-REFERENCE TO RELATED APPLICATION

This application is based upon and claims the benefit of priority of the prior Japanese Patent Application No. 2014-21398, filed on Feb. 6, 2014, the entire contents of which are incorporated herein by reference.

### FIELD

The present invention relates to a semiconductor device, a storage device, and a control method of the storage device. In more detail, the present invention relates to a semiconductor device and a storage device, both including a storage element having a latch circuit, and a control method of the storage device.

### BACKGROUND

Flash memory is known as a nonvolatile memory that stores nonvolatile data, in nonvolatile data is not erased even in a state where a power source voltage is not supplied. Flash memory implements a rewritable nonvolatile memory by selectively injecting charges into and extracting charges from a floating gate that is arranged between the gate of a MOS transistor and a substrate.

Since flash memory has a floating gate, the number of processes becomes larger than that of CMOS manufacturing processes when the flash memory is mounted on a semiconductor device together with logics that are formed in the CMOS manufacturing process, and therefore, the manufacturing cost is raised.

Various techniques are known in which an SRAM (Static Random Access Memory) can be manufactured by the CMOS manufacturing process to function as a nonvolatile memory.

It is described in Patent Literature 1 that a nonvolatile memory has two MISFET (Metal Insulator Semiconductor Field-Effect Transistor) type transistors having the same characteristics. In this nonvolatile memory, by controlling the voltage of a gate electrode of a first transistor at a voltage value other than the power source potential or ground potential for a specific period of time to control the conduction state of the first transistor, the resistance value of the first transistor is changed. Then, the current difference between the first and second transistors corresponds to “0”. Further, by controlling the voltage of a gate electrode of a second transistor at a voltage value other than the power source potential or ground potential for a specific period of time to control the conduction state of the second transistor, the resistance value of the second transistor is changed. Then, the current difference between the first and second transistors corresponds to “1”. In the nonvolatile memory in Patent Literature 1, the phenomenon that is known as the change in transistor performance by hot carriers due to an elapse of time (hereinafter, referred to as a hot carrier effect) is used and nonvolatile data is stored by shifting the threshold voltage of the transistor.

It is described in Patent Literature 2 that a nonvolatile memory has a flip-flop that latches data in a nonvolatile manner by irreversibly deteriorating an internal circuit by a voltage that is applied to a first or second bit line, and first to fourth switches. The first and second switches are connected between a first output terminal of the flip-flop and the first bit line, and the third and fourth switches are connected between a second output terminal and the second bit line, in which the output from the second output inverts the output of the first output terminal of the flip-flop. In the nonvolatile memory in Patent Literature 2, nonvolatile data is stored by using irreversible deterioration in the transistor due to the hot carrier effect.

It is described in Patent Literature 3 that a nonvolatile memory has first and second PMOS transistors formed on an N-type well, first and second NMOS transistors formed on a P-type well, first and second transfer MOS transistors and a drive circuit. The gate of the first transfer MOS transistor is electrically connected with a first word line. The source of the first transfer MOS transistor is electrically connected with a first data line. The drain of the first transfer MOS transistor is electrically connected with the drain of the first PMOS transistor, the source of the first NMOS transistor, the gate of the second PMOS transistor, and the gate of the second NMOS transistor. The gate of the second transfer MOS transistor is electrically connected with a second word line. The source of the second transfer MOS transistor is electrically connected with a second data line. The drain of the second transfer MOS transistor is electrically connected with the drain of the second PMOS transistor, the source of the second NMOS transistor, the gate of the first PMOS transistor, and the gate of the first NMOS transistor. The drive circuit controls voltages that are applied at least to the N-type well, the sources of the first and second PMOS transistors, the drains of the first and second NMOS transistors, the first word line, the second word line, the first data line, and the second data line. When the writing operation in relation to the first PMOS transistor is performed, the drive circuit applies a positive voltage whose absolute value is equal to or less than a junction withstand voltage to the N-type well and the sources of the first and second PMOS transistors. Further, the drive circuit applies a positive voltage to the first word line, applies the ground voltage to the second word line, and applies the ground voltage to the first data line. In the nonvolatile memory in Patent Literature 3, nonvolatile data is stored by the hot carrier effect.

A voltage characteristics adjustment method is described in Patent Literature 4 that the inventors of the present invention have invented. The method is a method for adjusting the voltage characteristics of a latch circuit configured by a plurality of gate-type transistors formed on a semiconductor substrate. In the voltage characteristics adjustment method in Patent Literature 4, first, a predetermined low voltage lower than the power source voltage applied during normal latch operation is applied to power source voltage application point of the latch circuit, to which the power source voltage is applied during normal latch operation. Next, by applying a predetermined high voltage higher than the power source voltage applied during normal latch operation to the power source voltage application point, variations in the threshold voltage between the transistors that form the latch circuit can be reduced.

### RELATED DOCUMENTS

[Patent Literature 1] Japanese Laid Open Patent Document No. 2005-353106

[Patent Literature 2] Japanese Laid Open Patent Document No. 2006-127737

[Patent Literature 3] Japanese Laid Open Patent Document) No. 2008-53269

[Patent Literature 4] International Publication Pamphlet No. WO 2010/143707

### SUMMARY

Since the nonvolatile memories in Patent Literatures 1 to 3 are SRAMs that can be manufactured in the CMOS manufacturing process to function as a nonvolatile memory, no additional processes are required, and therefore, the manufacturing cost of the nonvolatile memories will be raised. However, the nonvolatile memories in Patent Literatures 1 to 3 require a long time to store data, power consumption of the nonvolatile memories becomes large, since data is stored in the memory element by using the hot carrier effect.

Further, the nonvolatile memories in Patent Literatures 1 to 3 require long time to write data, since the storing operation is performed by selecting one bit each time for each memory element when data is stored.

In view of the above problems, an object of the present invention is to provide a nonvolatile memory whose manufacturing cost should not be raised and whose time required to write data should be shorter even if the nonvolatile memory is mounted with a logical circuit that is formed in the CMOS manufacturing process.

The semiconductor device according to the present invention has a plurality of storage elements each having a plurality of MOS transistors forming a latch circuit, a stored data setting unit configured to write inverted data of nonvolatile data that is read when each of the plurality of storage elements functions as a nonvolatile memory to each of the plurality of storage elements, and a voltage application unit configured to store nonvolatile data in each of the plurality of storage elements by applying a predetermined high voltage higher than a power source voltage applied during normal latch operation to each latch circuit.

In the semiconductor device according to the present invention, preferably, each of the plurality of storage elements has a first switch that turns on and off the connection between the latch circuit and the first data line and a second switch that turns on and off the connection between the latch circuit and the second data line which the inverted data of the data that is input to and out from the first data line is input to and output from, and when the voltage application unit applies a predetermined high voltage, the first switch turns off the connection between the latch circuit and the first data line, and the second switch turns off the connection between the latch circuit and the second data line.

In the semiconductor device according to the present invention, preferably, each of the plurality of storage elements has a pair of NMOS transistors that forms the latch circuit and the sources of which are grounded, and a pair of PMOS transistors that also forms the latch circuit and the sources of which are connected to the voltage application unit, and the first switch is a MOS transistor whose gate is connected to the word line, whose source is connected to the first data line, and whose drain is connected to the drains of one of the pair of NOMS transistors and one of the pair of PMOS transistors and to the gates of the other of the pair of NMOS transistors and the other of the pair of PMOS transistors, and the second switch is a MOS transistor whose gate is connected to the word line, whose source is connected to the second data line, and whose drain is connected to the drains of the other of the pair of NOMS transistors and the other of the pair of PMOS transistors and to the gates of the one of the pair of NMOS transistors and the one of the pair of PMOS transistors.

In the semiconductor device according to the present invention, preferably, the voltage application unit applies a predetermined high voltage to each latch circuit at a time.

In the semiconductor device according to the present invention, preferably, each of the plurality of storage elements is used as a volatile memory cell.

In the semiconductor device according to the present invention, preferably, the stored data setting unit has a data storage unit configured to store nonvolatile data and an inverted data output unit configured to output inverted data of nonvolatile data to each of the plurality of storage elements.

In the semiconductor device according to the present invention, preferably, the stored data setting unit has a data storage unit configured to store inverted data of nonvolatile data and an inverted data output unit configured to output data stored by the data storage unit to each of the plurality of storage elements.

In the semiconductor device according to the present invention, preferably, the stored data setting unit has a nonvolatile data input unit to which nonvolatile data or inverted data of nonvolatile data is input from the outside.

In the semiconductor device according to the present invention, preferably, the stored data setting unit further has a nonvolatile data output unit configured to output nonvolatile data or inverted data of nonvolatile data to the outside.

In the semiconductor device according to the present invention, preferably, the voltage application unit reads nonvolatile data by applying a voltage lower than the power source voltage applied during normal latch operation to the latch circuit as the power source voltage before applying the power source voltage to the latch circuit.

Preferably, the semiconductor device according to the present invention further has a nonvolatile data information storage unit configured to store information indicative of the state of data that is written to each of the plurality of storage elements by the stored data setting unit.

In the semiconductor device according to the present invention, preferably, information that is stored by the nonvolatile data information storage unit is information indicative of whether inverted data of the data that is stored in each of the plurality of storage elements by the stored data setting unit is used.

The storage device according to the present invention has a plurality of storage elements each having a plurality of MOS transistors forming the latch circuit, and a control unit configured to write inverted data of the nonvolatile data that is read when each of the plurality of storage elements functions as a nonvolatile memory cell to each of the plurality of storage elements, and to store nonvolatile data in each of the plurality of storage elements by applying a predetermined high voltage higher than the power source voltage applied during normal latch operation to each latch circuit.

In the storage device according to the present invention, preferably, the control circuit applies a predetermined high voltage to each latch circuit at a time.

In the storage device according to the present invention, preferably, each of the plurality of storage elements is used as a nonvolatile memory cell.

The storage device according to the present invention has a first storage unit that has a plurality of storage elements each having a plurality of MOS transistors forming a latch circuit, a second storage unit that has a plurality of storage elements each having a plurality of MOS transistors forming a latch circuit, and a control unit configured to write inverted data of the nonvolatile data that is read when each of the plurality of storage elements possessed by the first storage unit or the second storage unit functions as a nonvolatile memory cell to each of the plurality of storage elements possessed by the first storage unit or the second storage unit, to store nonvolatile data in the first storage unit or the second storage unit by applying a predetermined high voltage higher than the power source voltage applied during normal latch operation to the latch circuit in which the inverted data is stored, to determine whether or not the first storage unit functions as a nonvolatile memory, and to use the second storage unit as a nonvolatile memory in place of the first storage unit when determining that the first storage unit does not function as a nonvolatile memory.

In the storage device according to the present invention, preferably, the control unit counts the number of times data is written to the first storage unit as a nonvolatile memory cell and determines that the first storage unit no longer functions as a nonvolatile memory when the counted number of times exceeds a predetermined threshold value.

The method for controlling a storage device according to the present invention is a method for controlling a storage device that has a plurality of storage elements each having a plurality of MOS transistors forming a latch circuit, the method comprising writing inverted data of the nonvolatile data that is read when each of the plurality of storage elements functions as a nonvolatile memory to each of the plurality of storage elements, and storing nonvolatile data in each of the plurality of storage elements by applying a predetermined high voltage higher than the power source voltage applied during normal latch operation to each latch circuit in which the inverted data is stored.

In the method for controlling a storage device according to the present invention, preferably, a predetermined high voltage is applied at a time when nonvolatile data is stored in each of the plurality of storage elements.

Preferably, the method for controlling a storage device according to the present invention further comprises reading nonvolatile data by raising the power source voltage from a voltage lower than the power source voltage applied during normal latch operation when applying the power source voltage to the latch circuit.

In the method for controlling a storage device according to the present invention, preferably, error detection processing is performed on the read nonvolatile data and error correction processing is performed on the read nonvolatile data in accordance with the results of the error detection processing.

Preferably, the method for controlling a storage device according to the invention further comprises applying a voltage lower than the power source voltage applied during normal latch operation to the latch circuit as the power source voltage, and then applying a voltage higher than the power source voltage applied during normal latch operation to the latch circuit as the power source voltage.

In the method for controlling a storage device according to the present invention, preferably, each of the plurality of storage elements is used as a nonvolatile memory cell.

According to the present invention, nonvolatile data is stored in a latch circuit to which inverted data of the nonvolatile data is written by applying a predetermined high voltage, and therefore, nonvolatile data can be stored in a brief time without raising the manufacturing cost.

### BRIEF DESCRIPTION OF DRAWINGS

FIG. 1A is a circuit block diagram of a latch circuit and FIG. 1B is a diagram illustrating the voltage characteristics of a storage element illustrated in FIG. 1A;

FIG. 2A is a diagram illustrating the voltage characteristics when the power source voltage is reduced gradually in one of data states in the latch circuit that has the characteristics illustrated in FIG. 1B;

FIG. 2B is diagram illustrating the voltage characteristics when the power source voltage is reduced gradually in the other data state in the latch circuit that has the characteristics illustrated in FIG. 1B;

FIG. 3 is a diagram illustrating the voltage characteristics when the power source voltage is raised from 0 V in the latch circuit that has the characteristics illustrated in FIG. 1B;

FIG. 4A is a circuit block diagram of the latch circuit when a power source voltage of 3.2 is applied;

FIG. 4B is a diagram illustrating a bias state of a PMOS transistor that is in the on state in the state in FIG. 4A;

FIG. 4C is a diagram illustrating a bias state of the PMOS transistor that is in the off state in the state in FIG. 4A;

FIG. 4D is a diagram illustrating a bias state of an NMOS transistor that is in the off state in the state in FIG. 4A, and FIG. 4E is a diagram illustrating a bias state of the NMOS transistor that is in the on state in the state in FIG. 4A;

FIG. 5A is a circuit block diagram of an SRAM cell;

FIG. 5B is a diagram illustrating a shift of a threshold voltage of the PMOS transistor when a voltage of 3.2 V that is raised from 0 V is applied as a power source voltage to an SRAM in which the 1,000 SRAM cells illustrated in FIG. 5A are mounted;

FIG. 5C is a diagram illustrating a shift of the threshold voltage of the PMOS transistor that is on in the shift of the threshold voltage of the PMOS transistors illustrated in FIG. 5B;

FIG. 5D is a diagram illustrating a shift of the threshold voltage of the PMOS transistor that is on;

FIG. 6A is a diagram illustrating a relationship between the bias state and charges of the PMOS transistor that is in the on state;

FIG. 6B is a diagram illustrating a relationship between the bias state and charges of the PMOS transistor that is in the off state;

FIG. 6C is a diagram illustrating a change in the gate voltage-drain current characteristics of the PMOS transistor illustrated in FIG. 6A;

FIG. 6D is a diagram illustrating a change in the gate voltage-drain current characteristics of the PMOS transistor illustrated in FIG. 6B;

FIG. 6E is a diagram illustrating a change in a retention noise margin of the PMOS transistor illustrated in FIG. 6B;

FIG. 7A is a diagram illustrating a change in a butterfly curve when the power source voltage that is applied to the SRAM cell illustrated in FIG. 5A is raised higher than the rated voltage in one of data states;

FIG. 7B is a diagram illustrating a change in the butterfly curve when the power source voltage that is applied to the SRAM cell illustrated in FIG. 5A is raised higher than the rated voltage in the other data state;

FIG. 8 is a function block diagram of a semiconductor device according to a first embodiment;

FIG. 9 is a circuit block diagram partially illustrating an internal circuit of a constituent element that is mounted on the semiconductor device illustrated in FIG. 8;

FIG. 10 is a flowchart illustrating a processing flow of processing to store data that is written to the SRAM cell that is mounted on the semiconductor device illustrated in FIG. 8 as nonvolatile data;

FIG. 11 is a flowchart illustrating a processing flow of processing to write and read volatile data to and from, and to store and read nonvolatile data in and from the SRAM cell that is mounted on the semiconductor device illustrated in FIG. 8;

FIG. 12 is a function block diagram of a semiconductor device according to a second embodiment;

FIG. 13 is a circuit block diagram partially illustrating an internal circuit of a constituent element that is mounted on the semiconductor device illustrated in FIG. 12;

FIG. 14 a flowchart illustrating a processing flow of processing to store data that is written to an SRAM cell that is mounted on the semiconductor device illustrated in FIG. 12 as nonvolatile data;

FIG. 15 is a function block diagram of a semiconductor device according to a third embodiment;

FIG. 16 is a function block diagram of a storage device including a semiconductor device according to a fourth embodiment;

FIG. 17 is a function block diagram of a storage device including a semiconductor device according to a fifth embodiment;

FIG. 18 is a function block diagram of a semiconductor device according to a sixth embodiment;

FIG. 19 is a function block diagram of a semiconductor device according to a seventh embodiment;

FIG. 20 is a flowchart illustrating a processing flow of processing to write and read volatile data to and from, and to store and read nonvolatile data in and from an SRAM cell that is mounted on the semiconductor device illustrated in FIG. 19;

FIG. 21 is a flowchart illustrating an example of a processing flow of an SRAM according to the present embodiment; and

FIG. 22 is a flowchart illustrating another example of the processing flow of the SRAM according to the present embodiment.

### DESCRIPTION OF EMBODIMENTS

Hereinafter, with reference to the drawings, a semiconductor device, a storage device, and a control method of the storage device are explained. However, it should be noted that the technical scope of the present invention is not limited to embodiments below and encompasses the inventions described in the claims and equivalents thereof.

Before explaining a semiconductor device, a storage device, and a control method of the storage device according to the present invention, the voltage characteristics adjustment method of a latch circuit in Patent Literature 4 are explained in more detail.

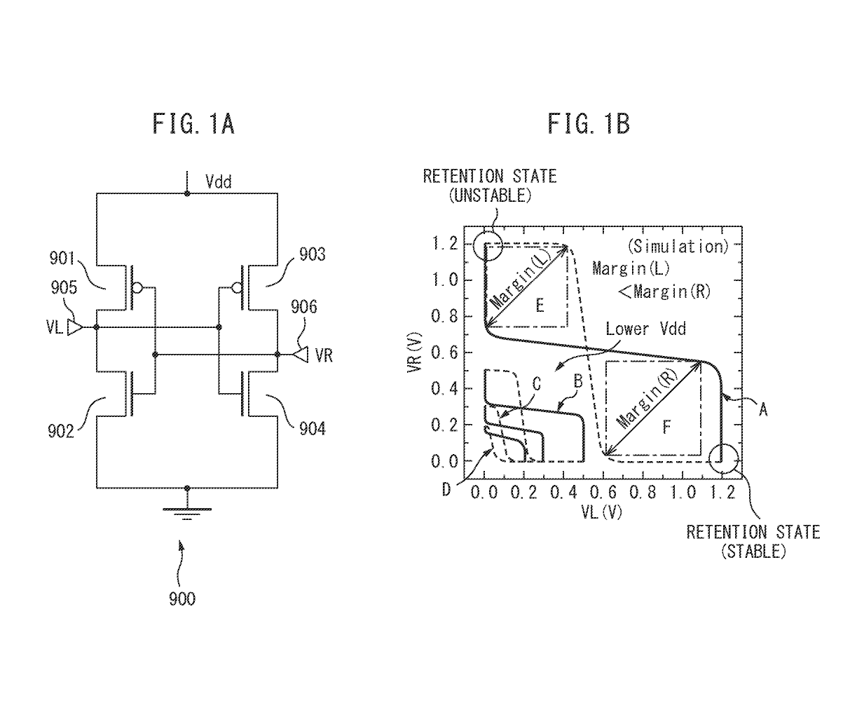

FIG. 1A is a circuit block diagram of a latch circuit.

A latch circuit 900 has a first PMOS transistor 901, a first NMOS transistor 902, a second PMOS transistor 903, a second NMOS transistor 904, a first input/output terminal 905, and a second input/output terminal 906. The gates of the first PMOS transistor and the first NMOS transistor are connected to the drains of the second PMOS transistor 903 and the second NMOS transistor 904, and to the second input/output terminal 906. The source of the first PMOS transistor 901 is connected to a power source voltage Vdd and the source of the first NMOS transistor 902 is grounded. The drains of the second PMOS transistor 903 and the second NMOS transistor 904 are connected to each other, and are connected to the gates of the first PMOS transistor 901 and the first NMOS transistor 902, and to the first input/output terminal 905. The first PMOS transistor 901 and the first NMOS transistor 902 form an inversion element that inverts data that is input to the second input/output terminal and outputs the inverted data to the first input/output terminal. The second PMOS transistor 903 and the second NMOS transistor 904 form an inversion element that inverts data that is input to the first input/output terminal and outputs the inverted data to the second input/output terminal. The latch circuit 900 is a latch circuit configured to retain inverted data of the first input/output terminal 905 at the second input/output terminal 906.

FIG. 1B is a diagram illustrating the voltage characteristics of the storage element illustrated in FIG. 1A. The curve illustrated in FIG. 1B is also referred to as a butterfly curve. The horizontal axis in FIG. 1B represents a voltage VL at the first input/output terminal 905 and the vertical axis in FIG. 1B represents a voltage VR at the second input/output terminal 906. The curve indicated by the solid line in FIG. 1B indicates the input/output voltage characteristics of the inversion element that is formed by the first PMOS transistor 901 and the first NMOS transistor 902. The curve indicated by the broken line indicates the input/output voltage characteristics of the inversion element that is formed by the second PMOS transistor 903 and the second NMOS transistor 904. An arrow A indicates the characteristics when the power source voltage is 1.2 V, an arrow B indicates the characteristics when the power source voltage is 0.5 V, an arrow C indicates the characteristics when the power source voltage is 0.3 V, and an arrow D indicates the characteristics when the power source voltage is 0.2 V. In FIG. 1B, a two-directional arrow E indicates a margin in the retention state where the signal level VL of the first input/output terminal 905 is an L level and the signal level VR of the second input/output terminal 906 is an H level when the power source voltage is 1.2 V. A two-directional arrow F indicates a margin in the retention state where the signal level VL of the first input/output terminal 905 is the H level and the signal level VR of the second input/output terminal 906 is the L level when the power source voltage is 1.2 V. The margins indicated by the two-directional arrows E and F, respectively, are indicated by the length of the diagonal line of the square having the maximum area that can be inscribed in the butterfly curve. In FIG. 1B, the square having the maximum area that can be inscribed in the butterfly curve is indicated by the alternate long and short dash line and the margin indicated by the two-directional arrow F is larger than the margin indicated by the two-directional arrow E. The comparatively small margin indicated by the arrow E of the two margins indicated by the two-directional arrows E and F, respectively, is also referred to as a retention noise margin.

As illustrated in FIG. 1B, when the power source voltage is reduced gradually, the difference between the two margins of the butterfly curve gradually becomes larger and one of the closed curves is eliminated completely. In other words, when the power source voltage reaches 0.2 V, the retention noise margin becomes zero. When the retention noise margin becomes zero, the retention state located in the closed curve whose margin becomes zero enters an unstable state and the data state changes to a stable state where the margin is not zero. In the example illustrated in FIG. 1B, the retention state where the signal level VL of the first input/output terminal 905 is the L level and the signal level VR of the second input/output terminal 906 is the H level is the unstable state. The retention state where the signal level VL of the first input/output terminal 905 is the H level and the signal level VR of the second input/output terminal 906 is the L level is the stable state. In the example illustrated in FIG. 1B, when the power source voltage reaches 0.2 V and the retention noise margin becomes zero, the signal level VL of the first input/output terminal 905 turns from the L level to the H level and the signal level VR of the second input/output terminal 906 turns from the H level to the L level. When the signal level VL of the first input/output terminal 905 is the H level and the signal level VR of the second input/output terminal 906 is the L level, even if the retention noise margin becomes zero, the signal level does not change.

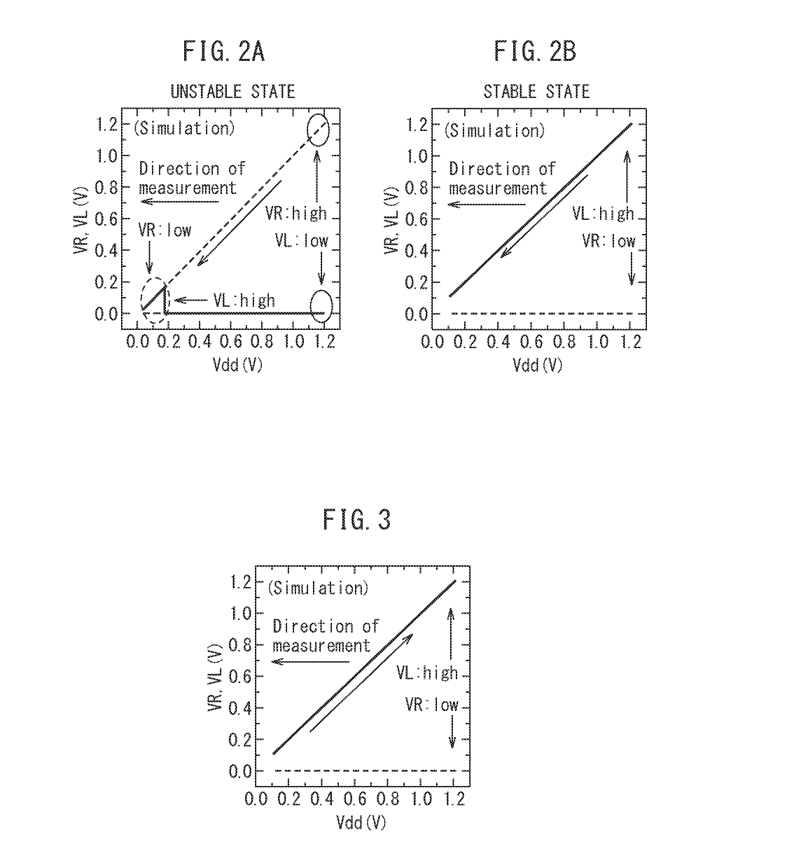

FIG. 2A is a diagram illustrating the voltage characteristics in which the power source voltage is reduced gradually when the signal level VL of the first input/output terminal 905 is the L level and the signal level VR of the second input/output terminal 906 is the H level in the latch circuit 900 that has the characteristics illustrated in FIG. 1B. FIG. 2B is a diagram illustrating the voltage characteristics in which the power source voltage is reduced gradually when the signal level VL of the first input/output terminal 905 is the H level and the signal level VR of the second input/output terminal 906 is the L level in the latch circuit 900 that has the characteristics illustrated in FIG. 1B. In FIGS. 2A and 2B, the solid line indicates the signal level VL of the first input/output terminal 905 and the broken line indicates the signal level VR of the second input/output terminal 906.

In the state where the signal level VL of the first input/output terminal 905 is the L level and the signal level VR of the second input/output terminal 906 is the H level, when the retention noise margin approaches zero, the signal levels of the first input/output terminal 905 and the second input/output terminal 906 are inverted. In other words, the signal level VL of the first input/output terminal 905 is inverted from the L level to the H level, and the signal level VR of the second input/output terminal 906 is inverted from the H level to the L level.

In the state where the signal level VL of the first input/output terminal 905 is the H level and the signal level VR of the second input/output terminal 906 is the L level, even when the retention noise margin approaches zero, the signal levels of the first input/output terminal 905 and the second input/output terminal 906 are not inverted.

In the latch circuit, when the power source voltage that is applied is reduced gradually and the retention noise margin approaches zero, the signal level of the input/output terminal of the latch circuit is retained in the data state, which is the stable state. In other words, the data state of the latch circuit is the data state, which is the stable state, in the region where the retention noise margin is zero, i.e., the power source voltage is low.

FIG. 3 is a diagram illustrating the voltage characteristics when the power source voltage is raised from 0 V in the latch circuit 900 that has the characteristics illustrated in FIG. 1B. In FIG. 3, the solid line indicates the signal level VL of the first input/output terminal 905 and the broken line indicates the signal level VR of the second input/output terminal 906.

When the power source voltage is equal to or less than 0.2 V and the retention noise margin is zero, the data state of the latch circuit 900 is the stable state. In other words, when the power source voltage is equal to or less than 0.2 V, the signal level VL of the first input/output terminal 905 turns to the H level and the signal level VR of the second input/output terminal 906 turns to the L level. Then, in the process in which the power source voltage is raised, the data state of the latch circuit 900 is maintained in the stable state. Thus, when the power source voltage of the latch circuit 900 is raised from 0 V, the data state of the latch circuit 900 selectively enters the state where the signal level VL of the first input/output terminal 905 turns to the H level and the signal level VR of the second input/output terminal 906 turns to the L level.

The case is considered where the power source voltage that is applied to the latch circuit 900 is raised from 0 V up to 3.2 V that is higher than a rated voltage of 1.2 V, which is the power source voltage in the normal operation. Since the power source voltage is raised from the state where the retention noise margin is zero, the data state of the latch circuit 900 is such that the signal level VL of the first input/output terminal 905 turns to the H level and the signal level VR of the second input/output terminal 906 turns to the L level.

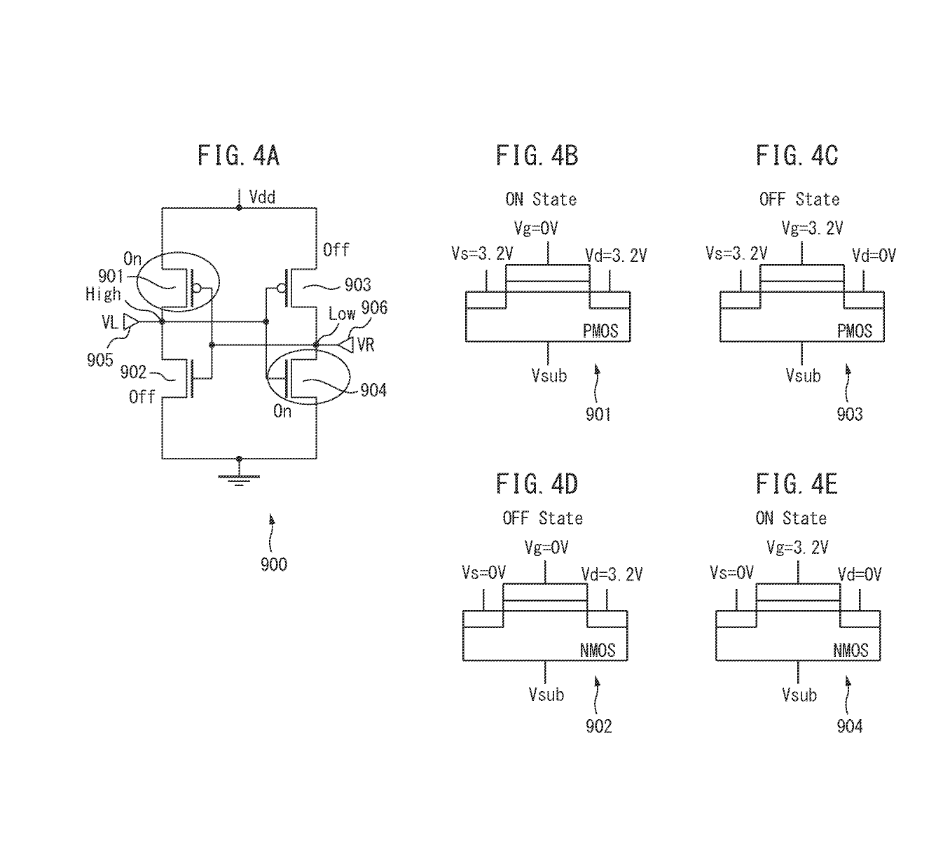

FIG. 4A is a circuit block diagram of the latch circuit 900 when a power source voltage of 3.2 V is applied. FIG. 4B is a diagram illustrating a bias state of the first PMOS transistor 901 that is in the on state in the state in FIG. 4A and FIG. 4C is a diagram illustrating a bias state of the second PMOS transistor 903 that is in the off state in the state in FIG. 4A. FIG. 4D is a diagram illustrating a bias state of the first NMOS transistor 902 that is in the off state in the state in FIG. 4A and FIG. 4E is a diagram illustrating a bias state of the second NMOS transistor 904 that is in the on state in the state in FIG. 4A.

Each of the first PMOS transistor 901 and the second NMOS transistor 904 that are in the on state in the stable state of the latch circuit 900 has a drive capacity comparatively larger than that of the second PMOS transistor 903 and the first NMOS transistor 902. In other words, each of the first PMOS transistor 901 and the second NMOS transistor 904 is a transistor whose threshold voltage is comparatively low. In the latch circuit 900, the threshold voltage of the first PMOS transistor 901 is lower than that of the second PMOS transistor 903 and the threshold voltage of the second NMOS transistor 904 is lower than that of the first NMOS transistor 902.

In the first PMOS transistor 901 and the second NMOS transistor 904 both having a comparatively low threshold voltage, a voltage of 3.2 V is applied between the gate and the source and between the gate and the drain. On the other hand, in the first NMOS transistor 902 having a comparatively high threshold voltage, the voltage of 3.2 V is applied between the gate and the drain, and in the second PMOS transistor 903, the voltage of 3.2 V is applied between the gate and the source.

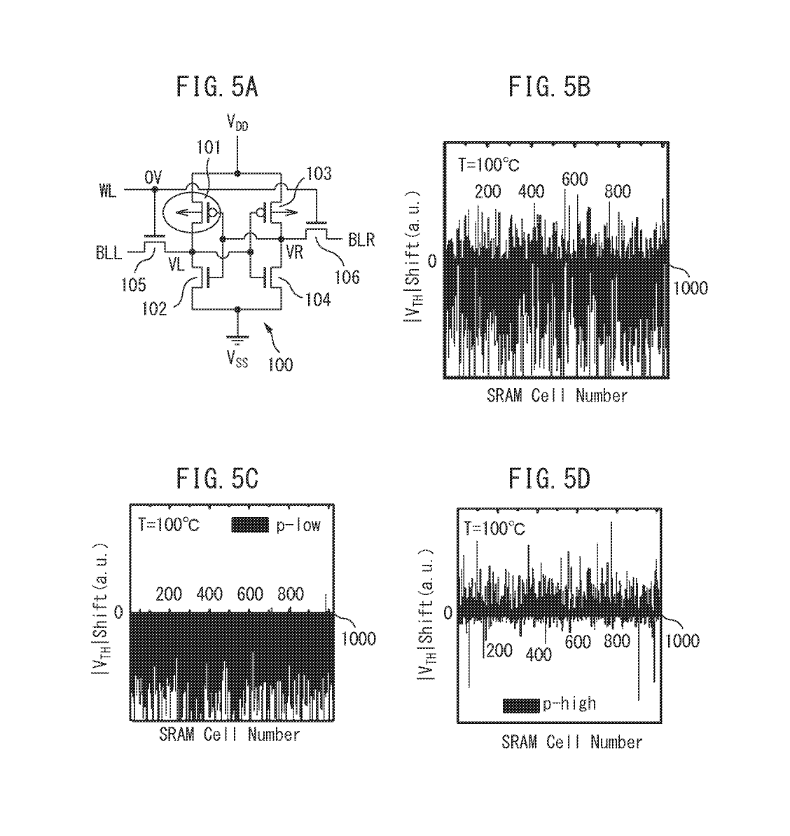

FIG. 5A is a circuit block diagram of an SRAM cell. FIG. 5B is a diagram illustrating a shift of the threshold voltage of the first PMOS transistor 901 when the voltage of 3.2 V, which is raised from 0 V, is applied as the power source voltage to an SRAM on which the 1,000 SRAM cells illustrated in FIG. 5A are mounted. FIG. 5C is a diagram illustrating a shift of the threshold voltage of the PMOS transistor that is on in the shift of the threshold value of the first PMOS transistor 901 illustrated in FIG. 5B, and FIG. 5D is a diagram illustrating a shift of the threshold voltage of the PMOS transistor that is on. In FIGS. 5B to 5D, the horizontal axis represents the numbers of the SRAM cells from 1 to 1,000 and the vertical axis represents the magnitude of the shift of the threshold voltage of the PMOS transistor in arbitrary units.

A first PMOS transistor 101 and a first NMOS transistor 102 of an SRAM cell 100 have the same structure and function as those of the first PMOS transistor 901 and the first NMOS transistor 902 of the latch circuit 900. A second PMOS transistor 103 and a second NMOS transistor 104 of the SRAM cell 100 have the same structure and function as those of the second PMOS transistor 903 and the second NMOS transistor 904 of the latch circuit 900. The SRAM cell 100 differs from the latch circuit 900 in that a first transfer MOS transistor 105 and a second transfer MOS transistor 107 are arranged in place of the first input/output terminal 905 and the second input/output terminal 906. The gate of the first transfer MOS transistor 105 is connected to a word line and the source is connected to a first bit line. The drain of the first transfer MOS transistor 105 is connected to the drains of the first PMOS transistor 101 and the first NMOS transistor 102, and to the gates of the second PMOS transistor 103 and the second NMOS transistor 104. The gate of a second transfer MOS transistor 106 is connected to the word line and the source is connected to a second bit line. The drain of a second transfer MOS transistor 108 is connected to the gates of the first PMOS transistor 101 and the first NMOS transistor 102, and to the drains of the second PMOS transistor 103 and the second NMOS transistor 104.

In FIG. 5B, the threshold voltage of the first PMOS transistor 901 to which a power source voltage of 3.2 V that is raised from 0 V is applied shifts randomly both in the magnitude and in the direction. However, as illustrated in FIGS. 5C and 5D, the threshold voltage of the first PMOS transistor 901 that is off shifts substantially in the minus direction and the threshold voltage of the first PMOS transistor 901 that is on shifts substantially in the plus direction.

As explained with reference to FIG. 3 and FIG. 4, when the power source voltage is raised from 0 V, the data state of the latch circuit is selectively determined so as to enter the stable state in accordance with the drive capacity of the transistor. In other words, when the power source voltage is raised from 0 V, the data state is brought about where the MOS transistor having a comparatively low threshold voltage turns on and the MOS transistor having a comparatively high threshold voltage turns off.

FIG. 5C illustrates that when the power source voltage of the latch circuit is raised from 0 V and a voltage higher than the rated voltage is applied, in the PMOS transistor having a comparatively high threshold voltage, the threshold voltage of the latch circuit shifts in the direction in which the threshold voltage becomes lower. On the other hand, FIG. 5D illustrates that when the power source voltage is raised from 0 V and a voltage higher than the rated voltage is applied, in the PMOS transistor having a comparatively low threshold voltage, the threshold voltage shifts in the direction in which the threshold voltage becomes higher.

The inventors of the present invention have found that variations in the threshold voltage between MOS transistors forming a latch circuit are reduced when the power source voltage of the latch circuit is raised from 0 V and a voltage higher than the rated voltage is applied. Further, the inventors of the present invention have found a voltage characteristics adjustment method of a latch circuit that is incorporated in an SRAM etc. by using this phenomenon.

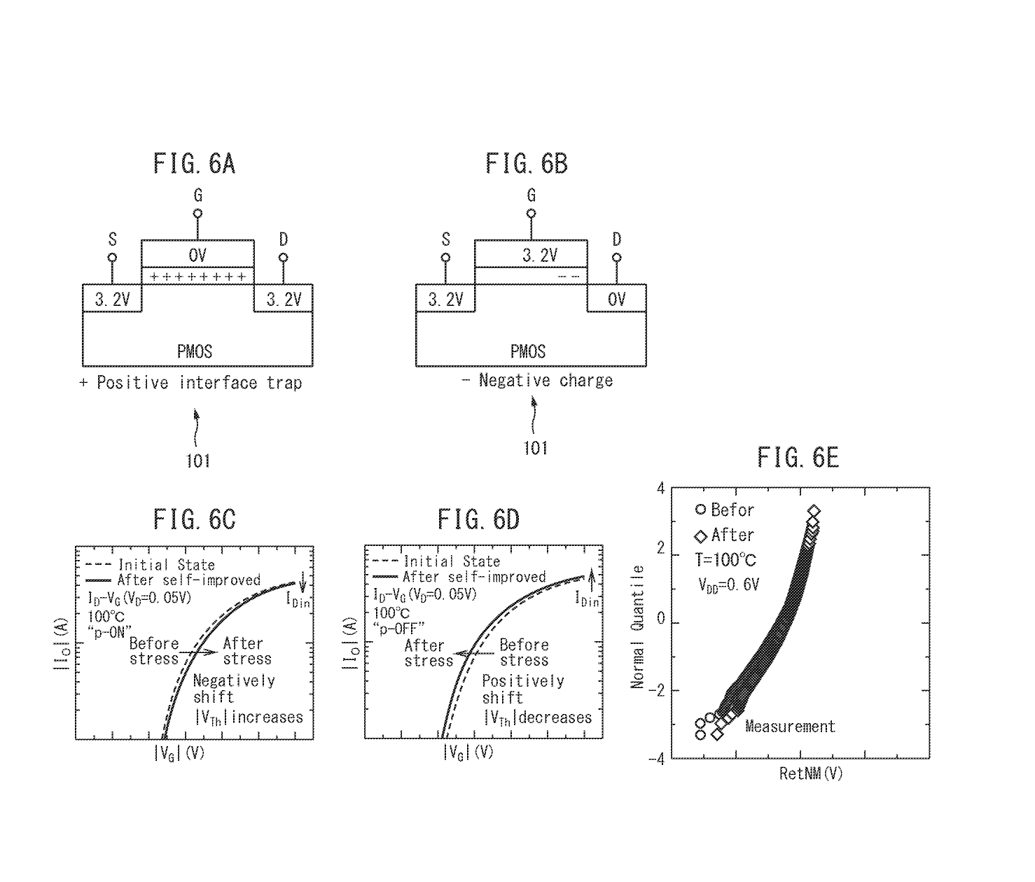

FIG. 6A is a diagram illustrating a relationship between the bias state and charges of the first PMOS transistor 101 in the on state, and FIG. 6B is a diagram illustrating a relationship between the bias state and charges of the first PMOS transistor 101 in the off state. FIG. 6C is a diagram illustrating a change in the gate voltage versus drain current characteristics of the first PMOS transistor 101 illustrated in FIG. 6A, and FIG. 6D is a diagram illustrating a change in the gate voltage versus drain voltage current characteristics of the first PMOS transistor 101 illustrated in FIG. 6B. FIG. 6E is a diagram illustrating a change in the retention noise margin of the first PMOS transistor 901 illustrated in FIG. 6B. In FIGS. 6C and 6D, the horizontal axis represents the gate voltage and the vertical axis represents the drain current, and the broken line indicates the characteristics before the power source voltage of 3.2 V is applied and the solid line indicates the characteristics after the power source voltage of 3.2 V is applied. In FIG. 6E, the horizontal axis represents the retention noise margin and the vertical axis represents the normal quantile in accordance with the magnitude of the retention noise margin before the power source voltage of 3.2 V is applied. The SRAM cell having a larger retention noise margin is located at an upper portion along the vertical axis and the SRAM cell having a smaller retention noise margin is located at a lower portion along the vertical axis. In FIG. 6E, circles indicate the characteristics before the power source voltage of 3.2 V is applied and rhombuses indicate the characteristics after the power source voltage of 3.2 V is applied.

The first PMOS transistor 101 to which the power source voltage of 3.2 V is applied in the on state is under the same conditions as the bias conditions of NBTI (Negative Bias Temperature Instability), and therefore, the threshold voltage shifts in the direction in which the threshold voltage becomes higher. On the other hand, in the first PMOS transistor 101 to which the power source voltage of 3.2 V is applied in the off state, the threshold voltage shifts in the direction in which the threshold voltage becomes lower resulting from that negative charges are injected to the oxide film in the vicinity of the drain.

As illustrated in FIG. 6E, the amount of an increase in the retention noise margin is larger in the SRAM cell having a smaller retention noise margin. This indicates that the SRAM cell that has a smaller retention noise margin and which is more unstable becomes more stable by the voltage characteristics adjustment method of a latch circuit that has been invented by the inventors of the present invention.

Further, the inventors of the present invention have found the use of the SRAM cell as a nonvolatile memory based on the phenomena to be described below by using the voltage characteristics adjustment method of a latch circuit that has been invented.

(1) When the power source voltage is raised from the state where the retention noise margin is zero, the SRAM cell selectively outputs the data state that becomes the stable state that is determined based on the drive capacity of the MOS transistor forming the latch circuit inside the SRAM cell. In other words, as explained with reference to FIG. 3 and FIG. 4, when the power source voltage that is applied to the latch circuit is raised from 0 V, the data state of the latch circuit enters a stable state, in which the stable state is a state located in the position where the magnitude of the margin of the butterfly curve is comparatively large.

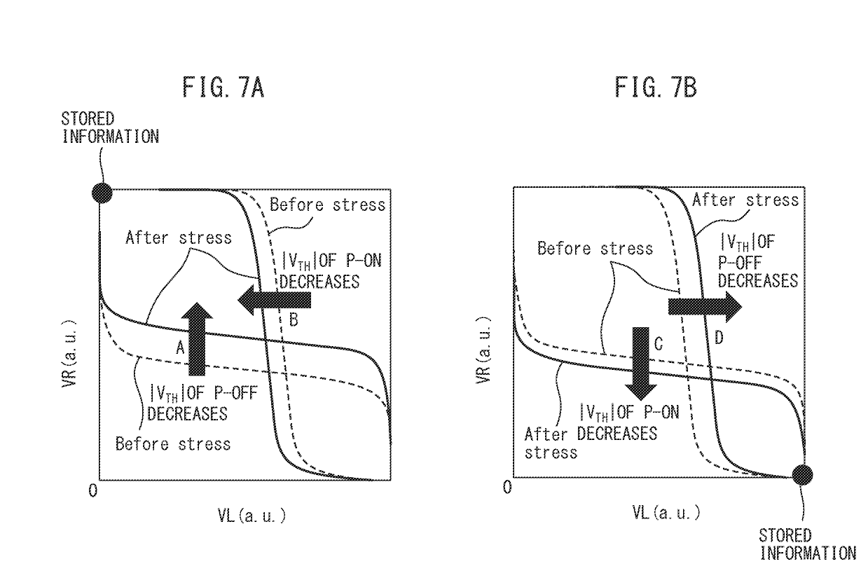

(2) When a power source voltage higher than the rated voltage is applied, in the MOS transistor forming the latch circuit inside the SRAM cell, the threshold voltage shifts in the direction in which the data state that is written to the latch circuit becomes unstable. Hereinafter, this phenomenon is explained in detail with reference to FIG. 7.

FIG. 7A is a diagram illustrating a change in the butterfly curve inwhich the power source voltage that is applied to the latch circuit is raised higher than the rated voltage when the signal level VL is the L level and the signal level VR is the H level in the SRAM cell 100 illustrated in FIG. 5A. FIG. 7B is a diagram illustrating a change in the butterfly curve in which the power source voltage that is applied to the latch circuit is raised higher than the rated voltage when the signal level VL is the H level and the signal level VR is the L level in the SRAM cell 100 illustrated in FIG. 5A. In FIGS. 7A and 7B, the horizontal axis represents the signal level VL at the drains of the first PMOS transistor 101 and the first NMOS transistor in arbitrary units. The vertical axis represents the signal level VR at the drains of the second PMOS transistor 103 and the second NMOS transistor 104 in arbitrary units. In FIGS. 7A and 7B, the broken line indicates the characteristics before the power source voltage of 3.2 V is applied and the solid line indicates the characteristics after the power source voltage of 3.2 V is applied.

In the state illustrated in FIG. 7A, the first PMOS transistor 101 and the second NMOS transistor 104 are off and the first NMOS transistor 102 and the second PMOS transistor 103 are on. Since the first PMOS transistor 101 is off, when the power source voltage higher than the rated voltage is applied, the threshold voltage of the first PMOS transistor 101 shifts in the direction in which the threshold voltage becomes lower. When the threshold voltage of the first PMOS transistor 101 shifts in the direction in which the threshold voltage becomes lower, the shape of the butterfly curve changes so that the margin of the butterfly curve in the direction of the data that is written to the SRAM cell 100 becomes smaller as indicated by the arrow A. On the other hand, since the second PMOS transistor 103 is off, when the power source voltage higher than the rated voltage is applied, the threshold voltage of the second PMOS transistor 103 shifts in the direction in which the threshold voltage becomes higher. When the threshold voltage of the second PMOS transistor 103 shifts in the direction in which the threshold voltage becomes higher, the shape of the butterfly curve changes so that the margin of the butterfly curve in the direction of the data that is written to the SRAM cell 100 becomes smaller as indicated by the arrow B.

In the state illustrated in FIG. 7B, the first PMOS transistor 101 and the second NMOS transistor 104 are on and the first NMOS transistor 102 and the second PMOS transistor 103 are off. Since the first PMOS transistor 101 is on, when the power source voltage higher than the rated voltage is applied, the threshold voltage of the first PMOS transistor 101 shifts in the direction in which the threshold voltage becomes higher. When the threshold voltage of the first PMOS transistor 101 shifts in the direction in which the threshold voltage becomes higher, the shape of the butterfly curve changes so that the margin of the butterfly curve in the direction of the data that is written to the SRAM cell 100 becomes smaller as indicated by the arrow C. On the other hand, since the second PMOS transistor 103 is off, when the power source voltage higher than the rated voltage is applied, the threshold voltage of the second PMOS transistor 103 shifts in the direction in which the threshold voltage becomes lower. When the threshold voltage of the second PMOS transistor 103 shifts in the direction in which the threshold voltage becomes lower, the shape of the butterfly curve changes so that the margin of the butterfly curve in the direction of the data that is written to the SRAM cell 100 becomes smaller as indicated by the arrow D.

As illustrated in FIGS. 7A and 7B, when the power source voltage higher than the rated voltage is applied, the threshold voltage of the MOS transistor forming the latch circuit shifts so that the data state that is written to the latch circuit of the SRAM cell becomes unstable.

Nonvolatile data can be stored in the SRAM cell 100 by controlling the SRAM cell 100 as follows, by using the above phenomena.

(1) Inverted data of the nonvolatile data that is read when the SRAM cell 100 functions as a nonvolatile memory is written to the SRAM cell.

(2) A predetermined high voltage higher than the power source voltage applied during normal latch operation is applied to the latch circuit of the SRAM cell 100 in which the inverted data of the nonvolatile data that is read when the SRAM cell 100 functions as a nonvolatile memory is stored.

Further, data stored in the SRAM cell 100 can be read as nonvolatile data by the above-described control by controlling the SRAM cell 100 as follows.

(1) The power source voltage of the latch circuit of the SRAM cell 100 is turned off.

(2) When the power source voltage is applied to the latch circuit of the SRAM cell 100, the power source voltage is raised from the state where the retention noise margin is zero up to the rated voltage.

Hereinafter, a first embodiment to a seventh embodiment is explained.

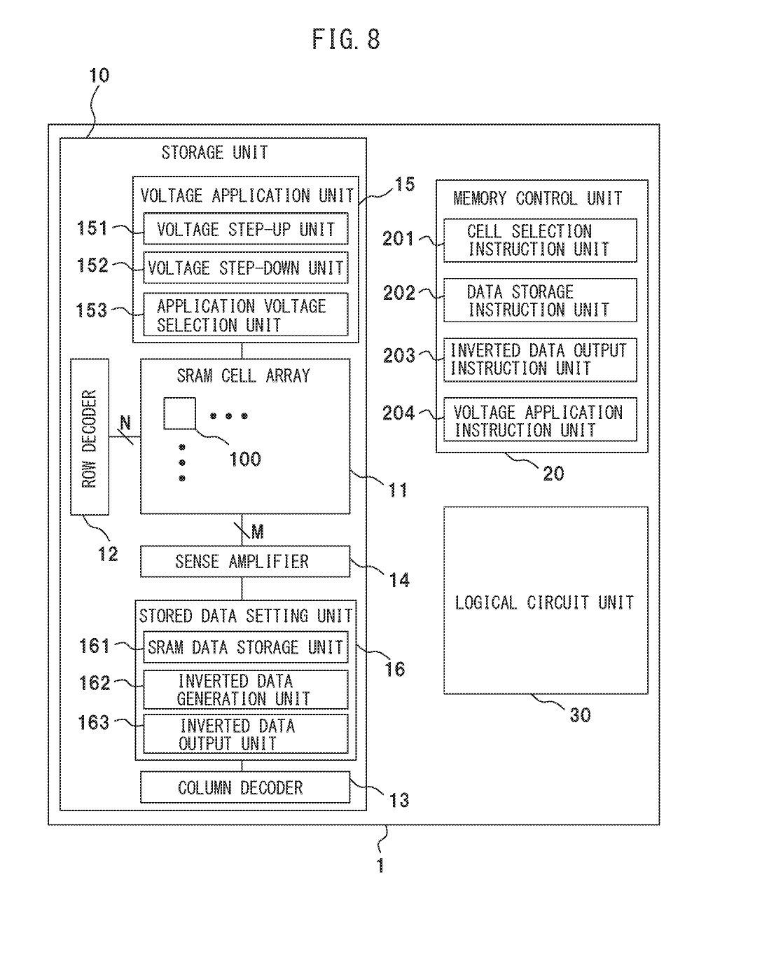

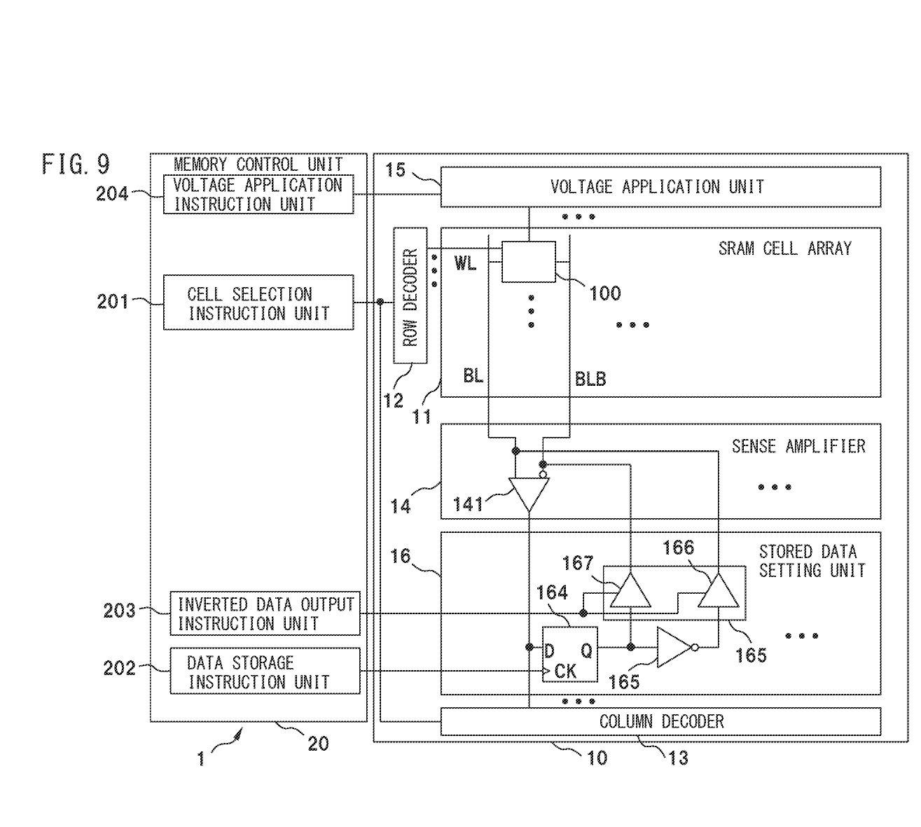

FIG. 8 is a function block diagram of a semiconductor device according to the first embodiment and FIG. 9 is a circuit block diagram partially illustrating an internal circuit of a constituent element that is mounted on the semiconductor device illustrated in FIG. 8.

A semiconductor device 1 has a storage unit 10, a memory control unit 20, and a logical circuit unit 30. The storage unit 10 has an SRAM cell array 11, a row decoder 12, a column decoder 13, a sense amplifier 14, a voltage application unit 15, and a stored data setting unit 16. The memory control unit 20 has a cell selection instruction unit 201, a data storage instruction unit 202, an inverted data output instruction unit 203, and a voltage application instruction unit 204. The storage unit 10 can be used as a volatile memory when it is not used as a nonvolatile memory.

The SRAM cell array 11 has a plurality of SRAM cells 100 arranged in the form of a matrix having N rows and M columns, a plurality of word lines WL arranged in the row direction, and a plurality of pairs of bit lines BL and BLB arranged in the column direction. The same word line is connected to the plurality of SRAM cells 100 arranged in the same row, respectively, and the same pair of bit lines BL and BLB is connected to the plurality of SRAM cells 100 arranged in the same column, respectively. When the row decoder 12 receives a row address selection signal, the row decoder 12 selects the word line WL corresponding to the received row address selection signal. When the column decoder 13 receives a column address selection signal, the column decoder 13 selects a pair of bit lines BL and BLB corresponding to the received column address selection signal and inputs data to the selected pair of bit lines BL and BLB and outputs data therefrom. The sense amplifier 14 has M amplification elements configured to amplify a signal transmitted from the SRAM cell 100 via a pair of bit lines BL and BLB.

The voltage application unit 15 has a voltage step-up unit 151, a voltage step-down unit 152, and an application voltage selection unit 153. The voltage step-up unit 151 has a charge pump and steps up a power source voltage supplied to the semiconductor device 1 to a voltage higher than the supplied power source voltage. The voltage step-down circuit 152 has a voltage division circuit and divides the power source voltage supplied to the semiconductor device 1 into a plurality of voltages lower than the supplied power source voltage and outputs a plurality of voltages ranging from 0 V to the power source voltage.

The application voltage selection unit 153 selects the voltage indicated by the application voltage signal that is transmitted from the voltage application instruction unit 204 from among the voltage to which stepped up by the voltage step-up unit 151 and the voltages into which divided by the voltage step-down unit 152. The application voltage selection unit 153 applies the selected voltage to the sources of the first PMOS transistors 101 and the second PMOS transistors 103 of the plurality of SRAM cells 100 arranged in the SRAM cell array 11.

The application voltage selection unit 153 receives an application voltage signal from the voltage application instruction unit 204, so as to gradually raise the voltage that the voltage step-down unit 152 applies from 0 V up to the rated voltage when the power source voltage is supplied to the semiconductor device 1. The application voltage selection unit 153 gradually raises the voltage that the voltage step-down unit 152 applies to the plurality of SRAM cells 100 from 0 V up to the rated voltage in accordance with the received signal. When the application voltage selection unit 153 gradually raises the voltage that is applied to the plurality of SRAM cells 100 from 0 V up to the rated voltage, the nonvolatile data that is stored in each of the plurality of SRAM cells 100 is retained in each of the plurality of SRAM cells 100 as data that can be rewritten by the SRAM operation. After raising the voltage that is applied to the plurality of SRAM cells 100 up to the rated voltage, the application voltage selection unit 153 maintains the voltage that is applied at the rated voltage.

The application voltage selection unit 153 receives an application voltage signal indicating instructions to apply the voltage stepped up by the voltage step-up unit 151 to the plurality of SRAM cells 100 when the inverted data of the nonvolatile data is written to each of the plurality of SRAM cells 100. When the application voltage selection unit 153 applies, in response to the received signal, a voltage higher than the rated voltage that is stepped up by the voltage step-up unit 151 at a time for a predetermined period of application time, the nonvolatile data is stored in each of the plurality of SRAM cells 100.

The stored data setting unit 16 has an SRAM data storage unit 161, an inverted data generation unit 162, and an inverted data output unit 163.

The SRAM data storage unit 161 has M data flip-flops 164. The data input terminal of each of the M data flip-flops 164 is connected to the output terminal of each of the M amplification elements 141 arranged in the sense amplifier 14. The clock input terminals of the M data flip-flops 164 are connected to the data storage instruction unit 202 of the memory control unit 20. Each of the M data flip-flops 164 stores data that is output from the amplification element 141 whose output terminal is connected to the data input terminal, when each of the M data flip-flops 164 receives a rise edge of a pulse signal that is transmitted from the data storage instruction unit 202.

The inverted data generation unit 162 has M inversion elements 165. The input terminal of each of the M inversion elements 165 is connected to the output terminal of each of the M data flip-flops 164. Each of the M inversion elements 165 outputs inverted data that is obtained by inverting the data output from the data flip-flop 164.

The inverted data output unit 163 has M pairs of a first inverted output buffer 166 and a second inverted output buffer 167. The data input terminal of each of the M first inverted output buffers 166 is connected to the output terminal of each of the M inversion elements 165. The data input terminal of each of the M second inverted output buffers 167 is connected to the output terminal of each of the M data flip-flops 164. The control terminals of the M pairs of the first inverted output buffer 166 and the second inverted output buffer 167 are connected to the inverted data output instruction unit 203 of the memory control unit 20. Each of the M first inverted output buffers 166 outputs the data that is output from the inversion element 165 to the data line BL, when each of the M first inverted output buffers 166 receives the inverted data output instruction signal indicating instructions to output the inverted data from the inverted data output instruction unit 203. Each of the M second inverted output buffers 167 outputs the data that is output from the output terminals of the M data flip-flops 164 to the data line BLB, when each of the M second inverted output buffers 167 receiving the inverted data output instruction signal indicating instructions to output the inverted data from the inverted data output instruction unit 203.

The cell selection instruction unit 201 sequentially selects the SRAM cell 100 whose written data is to be inverted by transmitting a row address selection signal to the row decoder 12 and by transmitting a column address selection signal to the column decoder 13. Further, when a predetermined read time elapses after transmitting the column address selection signal, the cell selection instruction unit 201 transmits a data storage instruction signal including information on the selected column to the data storage instruction unit 202 and the inverted data output instruction unit 203. The predetermined read time corresponds to the period of time from when the cell selection instruction unit 201 transmits the row address selection signal and the column address selection signal until the amplification element 141 of the sense amplifier 141 reads data from the selected SRAM cell 100.

When the cell selection instruction unit 201 receives a nonvolatile data storage instruction signal indicating instructions to store nonvolatile data in the SRAM cell 100 from a control unit (no illustration), the cell selection instruction unit 201 starts selecting the SRAM cell 100. First, the cell selection instruction unit 201 transmits a row address selection signal indicating instructions to select the first row to the row decoder 12 and transmits a column address selection signal indicating instructions to select the first column to the column decoder 13. Next, after the predetermined read time elapses, the cell selection instruction unit 201 transmits a data storage instruction signal including information indicative of that the first column is selected to the data storage instruction unit 202 and the inverted data output instruction unit 203. Next, the cell selection instruction unit 201 transmits a row address selection signal indicating instructions to select the second row to the row decoder 12 when a predetermined write time elapses after the inverted data output instruction unit 203 transmits the inverted data output instruction signal. The predetermined write time corresponds to the period of time from when the cell selection instruction unit 201 transmits the inverted data output instruction signal until the inverted data is written to the selected SRAM cell 100. When the row address selection signal that is transmitted to the row decoder 12 is changed, the SRAM cell 100 that is selected is changed from the SRAM cell 100 in the first row and the first column to the SRAM cell 100 in the second row and the first column.

Then, the cell selection instruction unit 201 changes the SRAM cell 100 that is selected each time the inverted data output instruction unit 203 transmits the inverted data output instruction signal and selects the SRAM cell 100 in the first row and the second column after selecting the SRAM cell 100 in the Nth row and the first column. Then, the cell selection instruction unit 201 sequentially selects the N SRAM cells 100 arranged in one and the same column from the first row and sequentially selects the SRAM cells arranged in the first row of the next column after selecting the SRAM cells arranged in the Nth row. The cell selection instruction unit 201 continues to select the SRAM cells 100 until the SRAM cell 100 in the Nth row and the Mth column is selected. Then, when the predetermined write time elapses after the inverted data output instruction unit 203 transmits the inverted data output instruction signal, the cell selection instruction unit 201 transmits an inverted data write completion signal to the voltage application instruction unit 204.

When the data storage instruction unit 202 receives a data storage instruction signal including information indicative of the selected column from the cell selection instruction unit 201, the data storage instruction unit 202 transmits a pulse signal to the data flip-flop 164 that is connected to the SRAM cell 100 that is arranged in the selected column.

The inverted data output instruction unit 203 transmits an inverted data output instruction signal to the first inverted output buffer 166 and the second inverted output buffer 167 that are arranged in the selected column when a predetermined FF write time elapses after the data storage instruction unit 202 transmits the pulse signal. The predetermined FF write time corresponds to the period of time from when the pulse signal is input to the clock terminal until the data flip-flop 164 stores the data that is input to the data input terminal.

The voltage application instruction unit 204 transmits an application voltage signal to the application voltage selection unit 153 so as to gradually raise the voltage that is output from the voltage step-down unit 152 from 0 V up to the rated voltage when the power source voltage is supplied to the semiconductor device 1.

When the voltage application instruction unit 204 receives the inverted data write completion signal from the cell selection instruction unit 201, the voltage application instruction unit 204 performs control so that all the first transfer MOS transistors 105 and the second transfer MOS transistors 106 of the SRAM cells 100 are turned off. Next, the voltage application instruction unit 204 transmits an application voltage signal indicating instructions to apply the voltage that is stepped up by the voltage step-up unit 151 to the plurality of SRAM cells 100 to the application voltage selection unit 153. By applying a voltage higher than the rated voltage to all the SRAM cells 100 at a time in the state where all the first transfer MOS transistors 105 and the second transfer MOS transistors 106 of the SRAM cells 100 are off, nonvolatile data is stored. Next, the voltage application instruction unit 204 transmits an application voltage signal indicating instructions to apply the rated voltage to the application voltage selection unit 153 after a predetermined application time elapses. Then, the voltage application instruction unit 204 transmits a nonvolatile data storage completion signal indicating that the nonvolatile data has been stored in each of the plurality of SRAM cells 100 to a control unit (no illustration).

The logical circuit unit 30 has various kinds of logical circuits formed by a plurality of CMOS transistors, and performs predetermined processing, such as writing of data to the storage unit 10 and reading of written data from the storage unit 10.

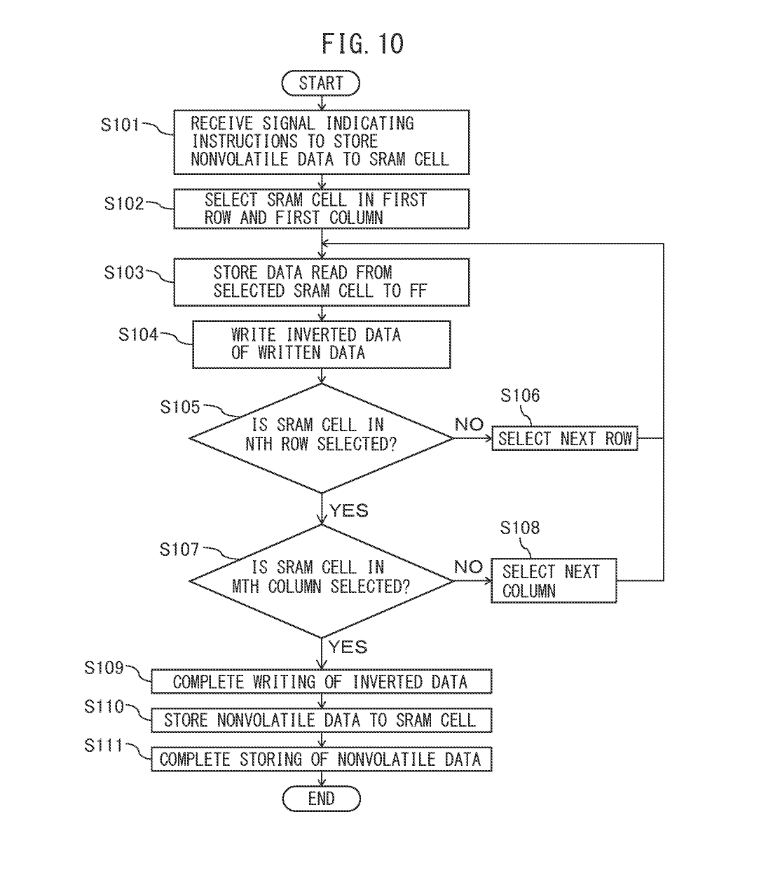

FIG. 10 is a flowchart illustrating a processing flow of processing when the memory control unit 20 stores data that is written to the plurality of SRAM cells 100 as nonvolatile data.

First, at step S101, the cell selection instruction unit 201 receives a nonvolatile data storage instruction signal indicating instructions to store nonvolatile data in the SRAM cell 100 from a control unit (no illustration).

Next, at step S102, the cell selection instruction unit 201 selects the SRAM cell 100 located in the first row and the first column of the SRAM cell array 11. The cell selection instruction unit 201 transmits a row address selection signal indicating instructions to select the first row to the row decoder 12 and transmits a column address selection signal indicating instructions to select the first column to the column decoder 13. Next, after a predetermined read time elapses, the cell selection instruction unit 201 transmits a data storage instruction signal including information indicative of that the first column is selected to the data storage instruction unit 202 and the inverted data output instruction unit 203.

Next, at step S103, when the inverted data output instruction unit 203 receives the data storage instruction signal including information indicative of that the first column is selected from the cell selection instruction unit 201, a pulse signal is transmitted to the clock input terminal of the data flip-flop 164 that is connected to the SRAM cell 100 in the first column. When the pulse signal is input to the clock input terminal, the data flip-flop 164 that is connected to the SRAM cell 100 in the first column stores the data that is output via the amplification element 141 in the first column and which is written in the first row and the first column.

Next, at step S104, the inverted data output instruction unit 203 transmits an inverted data output instruction signal to the first inverted output buffer 166 and the second inverted output buffer 167 that are arranged in the first column. The processing to transmit the inverted data output instruction signal, which is performed by the inverted data output instruction unit 203, is performed when the predetermined FF write time elapses after the data storage instruction unit 202 transmits the pulse signal. When the inverted data output instruction signal is transmitted, the first inverted output buffer 166 applies the inverted data of the data that is read to the data line BL by the SRAM cell 100 located in the first row and the first column to the data line BL in the first column. Further, the second inverted output buffer 167 applies the inverted data of the data that is read to the data line BLB by the SRAM cell 100 located in the first row and the first column to the data line BLB in the first column. When the inverted data of the data that is written to the SRAM cell 100 located in the first row and the first column is applied to the data lines BL and BLB in the first column, the applied inverted data is written to the SRAM cell 100 located in the first row and the first column.

Next, at step S105, the cell selection instruction unit 201 determines whether the SRAM cell 100 located in the Nth row is selected or not. The SRAM cell 100 located in the first row has been selected, and therefore, the processing proceeds to step S106.

When the processing proceeds to step S106, the cell selection instruction unit 201 selects the next row. The first row has been selected, and therefore, the cell selection instruction unit 201 selects the second row. Next, the processing returns to step S103.

Then, the processing at steps S103 to S106 is repeated until the cell selection instruction unit 201 selects the SRAM cell located in the Nth row and the first column, and thereby, the inverted data of the data that has been written to the SRAM cells located in the first column is written sequentially. Then, when the cell selection instruction unit 201 has selected the SRAM cell located in the Nth row and the first column, if the processing at step S105 is performed, the processing proceeds to step S107, since the SRAM cell 100 located in the Nth row has been selected.

Next, at step S107, the cell selection instruction unit 201 determines whether the SRAM cell 100 located in the Mth column is selected or not. The SRAM cell 100 located in the first column has been selected, and therefore, the processing proceeds to step S108.

When the processing proceeds to step S108, the cell selection instruction unit 201 selects the next column. The first column has been selected, and therefore, the cell selection instruction unit 201 selects the second column. Next, the processing returns to step S103. Then, the processing at steps S103 to S107 is repeated until the cell selection instruction unit 201 selects the SRAM cell 100 located in the Nth row and the Mth column and thereby the inverted data is written sequentially to the SRAM cells 100 located in the second column to the Mth column. Then, when the cell selection instruction unit 201 has selected the SRAM cell 100 located in the Nth row and the Mth column, if the processing at S107 is performed, the SRAM cell 100 located in the Mth column has been selected, and therefore, the processing proceeds to step S109.

When the processing proceeds to step S109, the cell selection instruction unit 201 transmits an inverted data write completion signal to the voltage application instruction unit 204.

Next, at step S110, the voltage application instruction unit 204 having received the inverted data write completion signal from the cell selection instruction unit 201 transmits an application voltage signal indicating instructions to apply the voltage stepped up by the voltage step-up unit 151 to the plurality of SRAM cells 100 to the application voltage selection unit 153. Next, the voltage application instruction unit 204 transmits an application voltage signal indicating instructions to apply the rated voltage to the application voltage selection unit 153 after a predetermined application time elapses. By the application voltage selection unit 153 having received the application voltage signal applying a voltage higher than the rated voltage stepped up by the voltage step-up unit 151 at a time for a predetermined application time, nonvolatile data is stored in each of the plurality of SRAM cells 100.

Then, at step S111, the voltage application instruction unit 204 transmits a nonvolatile data storage completion signal indicating that nonvolatile data has been stored in each of the plurality of SRAM cells 100 to a control unit (no illustration).

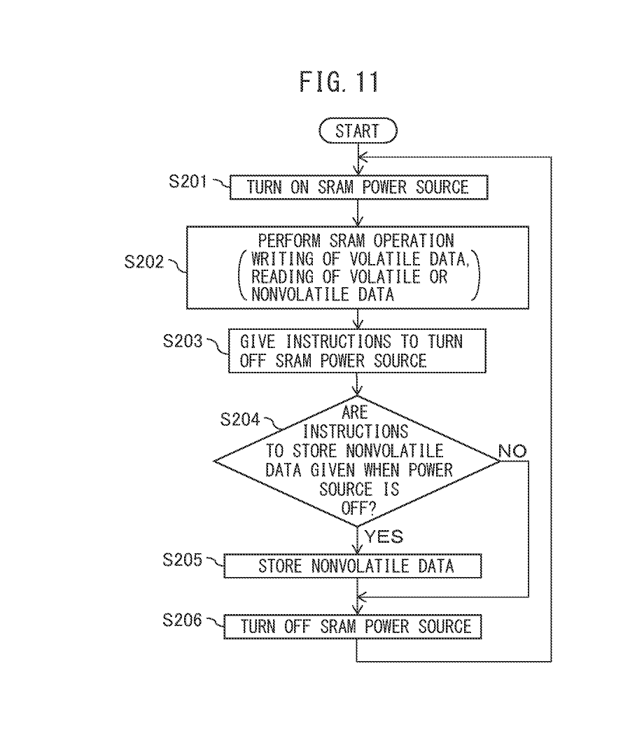

FIG. 11 is a flowchart illustrating a processing flow of processing to write and read volatile data to and from, and to store and read nonvolatile data in and from the SRAM cell 100 that is mounted on the semiconductor device 1.

First, at step S201, the power sources of the plurality of SRAM cells 100 are turned on. Next, at step S202, the normal operation of the SRAM, i.e., wring and reading of volatile data are performed on each of the plurality of SRAM cells 100.

The reading at S202 includes reading of nonvolatile data. Whether the data that has been read to a certain address is nonvolatile data or volatile data depends on the turning off of the SRAM power source at step S206, the turning on of the SRAM power source at step S201, or the writing of volatile data to the address at step S202, whichever has been performed the most recent. In other words, if the turning off of the SRAM power source at step 206 and the turning on of the SRAM power source at step S201 have been performed the most recent, nonvolatile data is read. If the processing to store nonvolatile data at step S205 has been performed, even though the number of times is one, the nonvolatile data that has been stored the most recent is read. If the processing to store nonvolatile data at step S205 has never once been performed, the nonvolatile data in the initial state that has been stored in factory shipment is read. When the writing of nonvolatile data to the address at step S202 has been performed the most recent, the volatile data that is written by the writing processing is read. Even if the writing of nonvolatile data at step S202 is the most recent action, the writing of nonvolatile data to an address other than the address is not the writing of nonvolatile data to the above-described address at step S202.

Next, when instructions to turn off the SRAM power source are given at S203, the processing proceeds to step S204. Next, if instructions to store nonvolatile data are given when the SRAM power source is off at step S204, the processing proceeds to step S205. If the instructions to store nonvolatile data are not given when the SRAM power source is off at step S204, the processing proceeds to step S206.

When the processing proceeds to step S205, the processing explained with reference to FIG. 10 is performed and nonvolatile data is stored. Next, the processing proceeds to step S206. When the processing proceeds to step S206, the SRAM power source is turned off. Then, when the power source is turned on again at step S201, the nonvolatile data stored in the SRAM cell 100 is retained as data that can be written by the SRAM operation. Next, the SRAM cell 100 performs the normal SRAM operation at step S202.

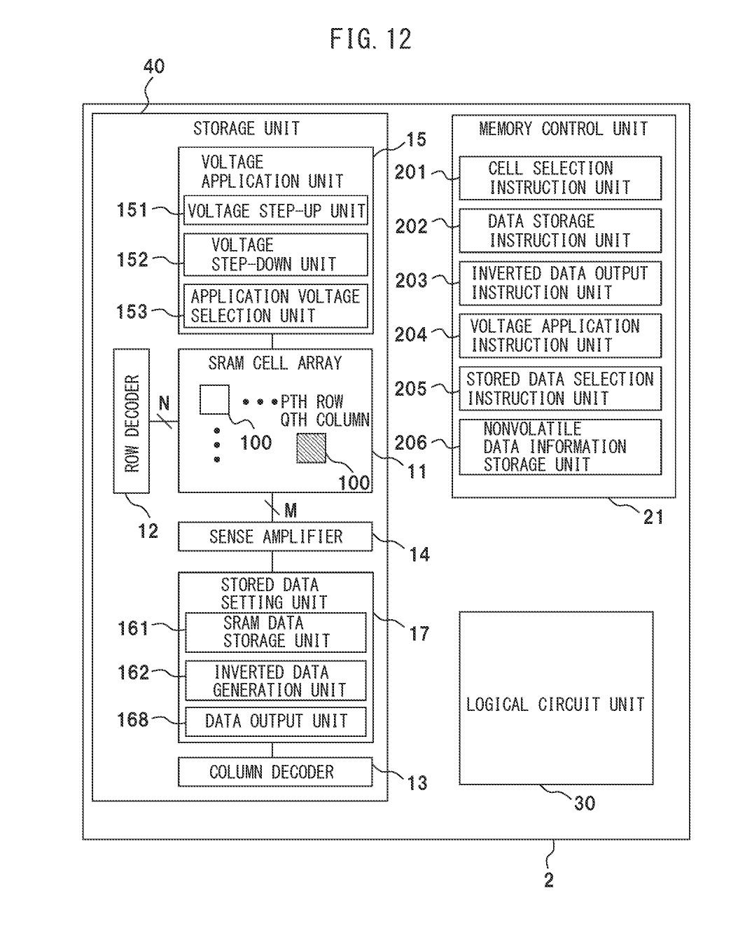

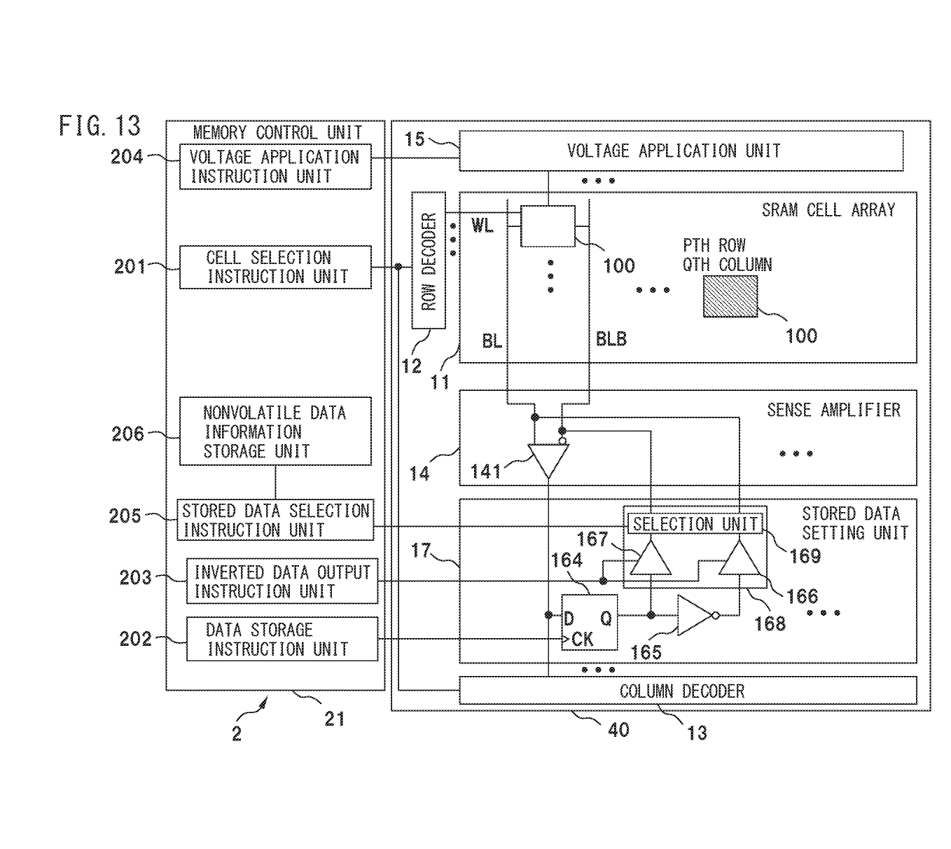

FIG. 12 is a function block diagram of a semiconductor device according to a second embodiment and FIG. 13 is a partial circuit block diagram of an internal circuit of a constituent element that is mounted on the semiconductor device illustrated in FIG. 12.

A semiconductor device 2 differs from the semiconductor device 1 in having a storage unit 40 in place of the storage unit 10. Further, the semiconductor device 2 differs from the semiconductor device 1 in having a memory control unit 21 in place of the memory control unit 20.

The storage unit 40 differs from the storage unit 10 in having a stored data setting unit 17 in place of the stored data setting unit 16. The stored data setting unit 17 differs from the stored data setting unit 16 in having a data output unit 168 in place of the inverted data output unit 163. The data output unit 168 differs from the inverted data output unit 163 in having a selection unit 169.

The memory control unit 21 differs from the memory control unit 20 in having a stored data selection instruction unit 205 and a nonvolatile data information storage unit 206.

The semiconductor device 2 determines data that is to be stored in each SRAM cell 100 depending on the data that is to be stored in the SRAM cell 100 that is the most unlikely to store the signal of “0” or “1”, since the balance of the butterfly curve measured by the test in factory shipment. is the worst. The case is explained where the balance of the butterfly curve of the SRAM cell 100 arranged in the Pth row and the Qth column is the worst and “1” is easily stored, but “0” is unlikely to be stored.

The selection unit 169 selects the data line BL or BLB to which each of the output signals of the first inverted output buffer 166 and the second inverted output buffer 167 is output based on a storage data selection signal that is transmitted from the stored data selection instruction unit 205.

The stored data selection instruction unit 205 determines whether or not the data that has been written to each SRAM cell 100 is to be stored in each SRAM cell 100 in accordance with the data that is stored in the SRAM cell 100 arranged in the Pth row and the Qth column of the SRAM cell array 11.

The stored data selection instruction unit 205 determines whether the data that has been written to the SRAM cell 100 arranged in the Pth row and the Qth column is “0” or “1”. If “1” has been written to the SRAM cell 100 arranged in the Pth row and the Qth column, the stored data selection instruction unit 205 sets the selection unit 169 so that the inverted data of the data that has been written to each SRAM cell 100 is written. In other words, the stored data selection instruction unit 205 transmits a stored data selection signal indicating instructions to apply the output signal of the first inverted output buffer 166 to the data line BL and to apply the output signal of the second inverted output buffer 167 to the data line BLB to the selection unit 169.

If “0” has been written to the SRAM cell 100 arranged in the Pth row and the Qth column, the stored data selection instruction unit 205 sets the selection unit 169 so that the data that has been written to each SRAM cell 100 is written. In other words, the stored data selection instruction unit 205 transmits a storage data selection signal indicating instructions to apply the output signal of the first inverted output buffer 166 to the data line BLB and to apply the output signal of the second inverted output buffer 167 to the data line BL to the selection unit 169.

The nonvolatile data information storage unit 206 stores information indicative of whether the inverted data of the nonvolatile data stored in each SRAM cell 100 by the stored data setting unit is used. If the inverted data of the data that has been written to each SRAM cell 100 is written to the SRAM cell 100, the nonvolatile data information storage unit 206 stores information indicative of the use of the stored nonvolatile data. If the data that has been written to each SRAM cell 100 is written to the SRAM cell 100, the nonvolatile data information storage unit 206 stores information indicative of the use of the inverted data of the stored nonvolatile data.

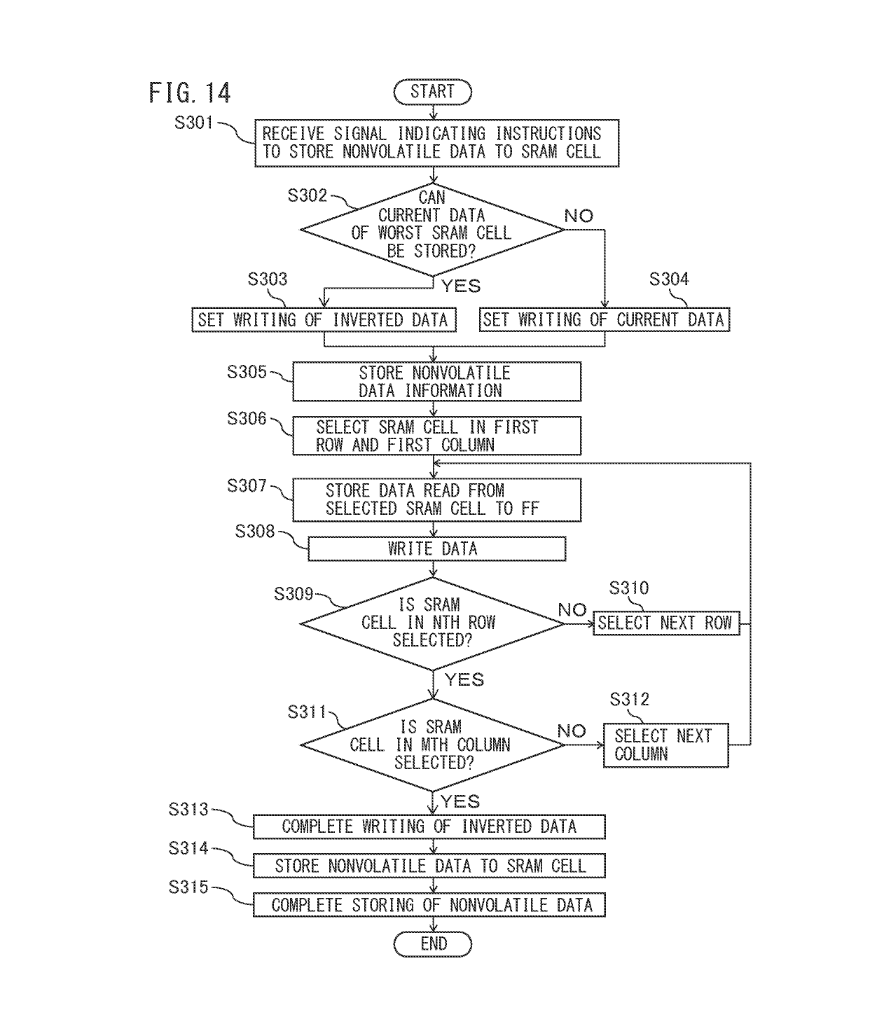

FIG. 14 is a flowchart illustrating a processing flow of processing when the memory control unit 21 stores the data written to the plurality of SRAM cells 100 as nonvolatile data.

First, at step S301, the cell selection instruction unit 201 receives a nonvolatile data storage instruction signal indicating instructions to store nonvolatile data in the SRAM cell 100 from a control unit (no illustration).

Next, at step S302, the stored data selection instruction unit 205 determines whether or not the data currently written to the SRAM cell 100 whose butterfly curve balance is in the worst condition can be stored. The SRAM cell 100 in which “0” is unlikely to be stored and which is arranged in the Pth row and the Qth column is the SRAM cell 100 whose condition is the worst, and therefore, if “1” has been written to the SRAM cell 100 that is arranged in the Pth row and the Qth column, the processing proceeds to step S303. On the other hand, If “0” has been written to the SRAM cell 100 that is arranged in the Pth row and the Qth column, the processing proceeds to step S304.

When the processing proceeds to step S303, the stored data selection instruction unit 205 sets the selection unit 169 so that the inverted data of the data that is currently written to each SRAM cell 100 is written. The selection unit 169 is set so that a stored data selection signal indicating instructions to apply the output signal of the first inverted output buffer 166 to the data line BL and to apply the output signal of the second inverted output buffer 167 to the data line BLB is applied. Next, the processing proceeds to step S305.

When the processing proceeds to step S304, the stored data selection instruction unit 205 sets the selection unit 169 so that the data that is currently written to each SRAM cell 100 is written. The selection unit 169 is set so that a stored data selection signal indicating instructions to apply the output signal of the first inverted output buffer 166 to the data line BLB and to apply the output signal of the second inverted output buffer 167 to the data line BL is applied. Next, the processing proceeds to step S305.

When the processing proceeds to step S305, the stored data selection instruction unit 205 stores information indicative of whether the inverted data of the data stored in each SRAM cell 100 by the stored data setting unit is used in the nonvolatile data information storage unit 206.

Next, the same processing as that at steps S102 to S111 is performed at steps S306 to S315. At step S308, based on the determination at step S302, data is written to each SRAM cell 100 based on the setting state of the selection unit 169 set at step S303 or S304.

The processing to write and read volatile data to and from, and to read nonvolatile data from the storage unit 40 of the semiconductor device 2 is performed in the same manner as that of the processing for the storage unit 10 of the semiconductor device 1 explained with reference to FIG. 11.

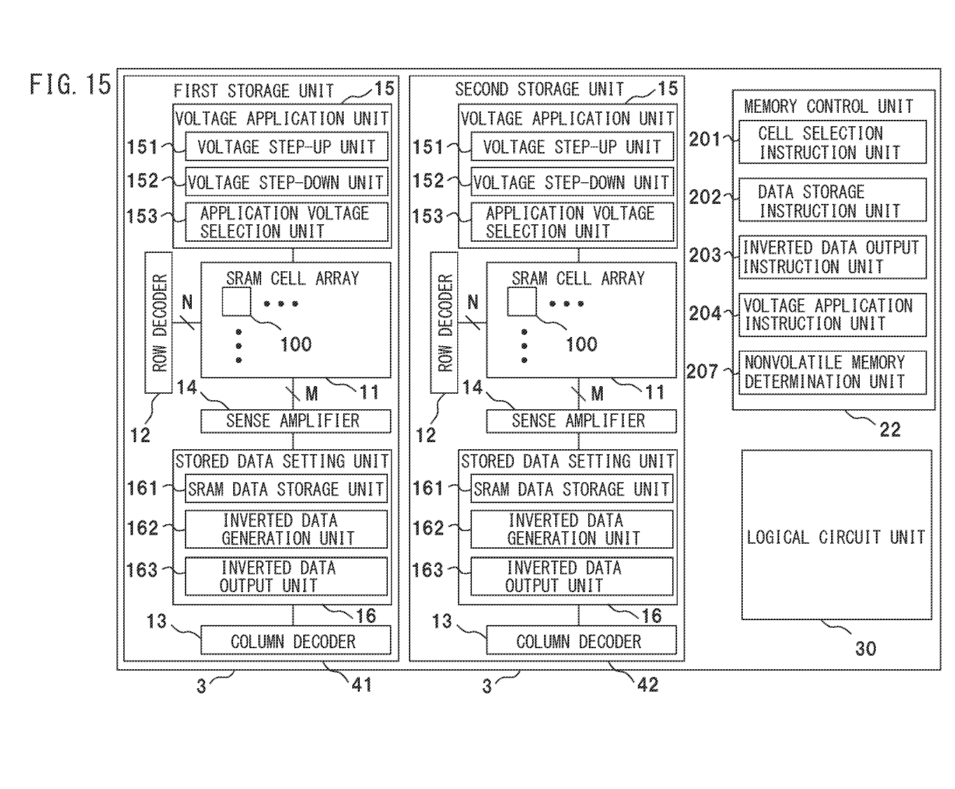

FIG. 15 is a function block diagram of a semiconductor device according to a third embodiment.

A semiconductor device 3 differs from the semiconductor device 1 in having a first storage unit 41 and a second storage unit 42 in place of the storage unit 10. Further, the semiconductor device 3 differs from the semiconductor device 1 in having a memory control unit 22 in place of the memory control unit 20.

The processing to write and read volatile data to and from, and to store and read nonvolatile data in and from the first storage unit 41 and the second storage unit 42 of the semiconductor device 3 is performed in the same manner as that of the processing for the storage unit 10 of the semiconductor device 1 explained with reference to FIG. 11.

Each of the first storage unit 41 and the second storage unit 42 has the same configuration and function as those of the storage unit 10. Each of the first storage unit 41 and the second storage unit 42 is selectively used as a nonvolatile memory by the memory control unit 22. First, the first storage unit 41 is used as a nonvolatile memory. Next, when it is determined that the first storage unit 41 does not function as a nonvolatile memory, the second storage unit 42 is used as a nonvolatile memory. Each of the first storage unit 41 and the second storage unit 42 can be used as a volatile memory when they are not used as a nonvolatile memory.

A nonvolatile memory determination unit 207 determines whether or not the first storage unit 41 functions as a nonvolatile memory. Specifically, the nonvolatile memory determination unit 207 counts the number of times nonvolatile data is written to the SRAM cell 100 of the first storage unit 41 and when the counted number of times exceeds a predetermined threshold value, the nonvolatile memory determination unit 207 determines that the first storage unit 41 no longer functions as a nonvolatile memory. When determining that the first storage unit 41 no longer functions as a nonvolatile memory, the nonvolatile memory determination unit 207 switches the memory that is used as a nonvolatile memory from the first storage unit 41 to the second storage unit 42.

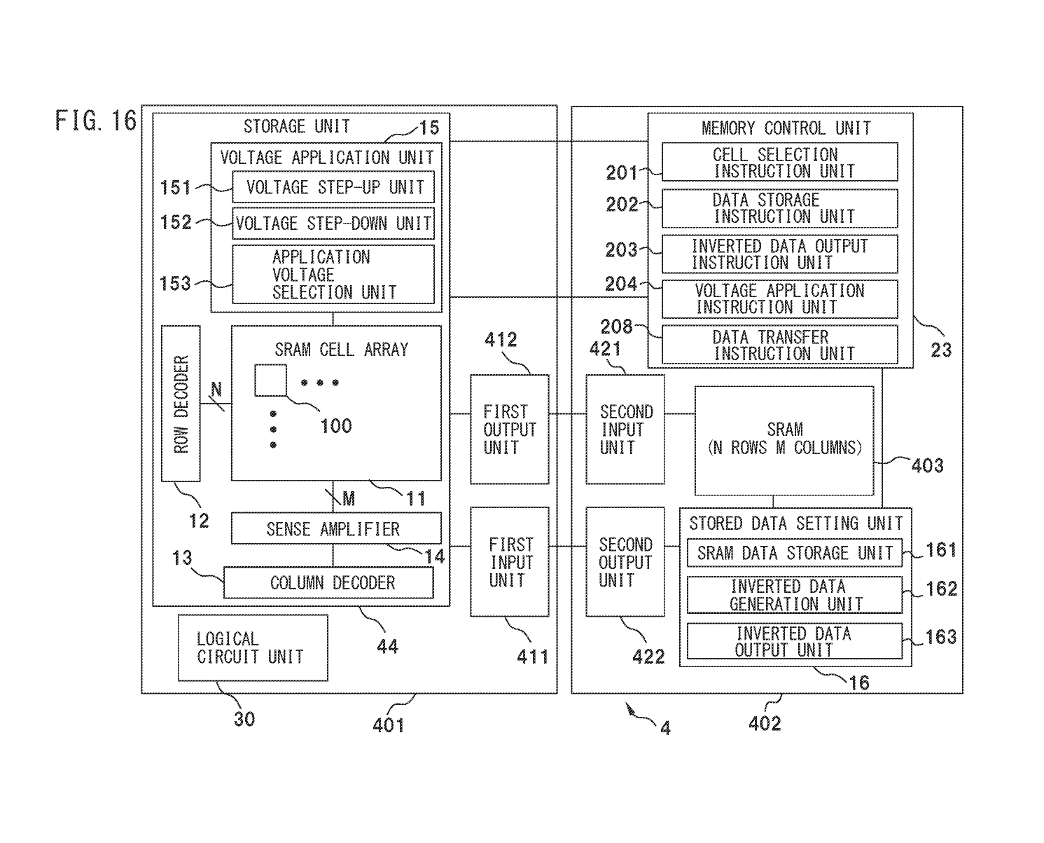

FIG. 16 is a function block diagram of a storage device including a semiconductor device according to a fourth embodiment.

A storage device 4 has a first semiconductor device 401 and a second semiconductor device 402. The first semiconductor device 401 has the logical circuit unit 30, a storage unit 44, a first input unit 411, and a first output unit 412. The storage unit 44 differs from the storage unit 10 in not having the stored data setting unit 16.

The second semiconductor device 402 is, in an example, a CPU (Central Processing Unit) and is also a semiconductor device that controls a control system formed by a plurality of semiconductor devices including the first semiconductor device 401. The second semiconductor device 402 has the stored data setting unit 16, a memory control unit 23, an SRAM 403 having a plurality of SRAM cells 100 arranged in the form of a matrix having N rows and M columns, a second input unit 421, and a second output unit 422. The stored data setting unit 16 is controlled by the memory control unit 23 so as to write the inverted data of the data that is read from each SRAM cell 100 of the SRAM 403 to the SRAM cell 100 of the SRAM cell array 11.

The memory control unit 23 differs from the memory control unit 20 in having a data transfer instruction unit 208. The data transfer instruction unit 208 controls the storage unit 44 and the SRAM 403 so as to write the data that is read from each SRAM cell 100 of the SRAM cell array 11 to the SRAM cell 100 that is arranged in the corresponding position of the SRAM 403. For example, the data transfer instruction unit 208 writes the data that is read from the SRAM cell 100 located in the first row and the first column of the SRAM cell array 11 to the SRAM cell 100 located in the first row and the first column of the SRAM 403. Further, the data transfer instruction unit 208 writes the data that is read from the SRAM cell 100 located in the Nth row and the Mth column of the SRAM cell array 11 to the SRAM cell 100 located in the Nth row and the Mth column of the SRAM 403.

The first output unit 412 transmits the data that is read from each SRAM cell 100 of the SRAM cell array 11 to the second input unit 421. The second input unit 421 writes the received data to each SRAM cell 100 of the SRAM 403. The second output unit 422 transmits the inverted data of the data that is read from each SRAM cell 100 of the SRAM 403 to the first input unit 411. The first input unit 411 writes the received data to each SRAM cell 100 of the SRAM cell array 11.

The processing to write and read volatile data to and from, and to read nonvolatile data from the storage unit 44 of the first semiconductor device 401 is performed in the same manner as that of the processing for the storage unit 10 of the semiconductor device 1 explained with reference to FIG. 11.

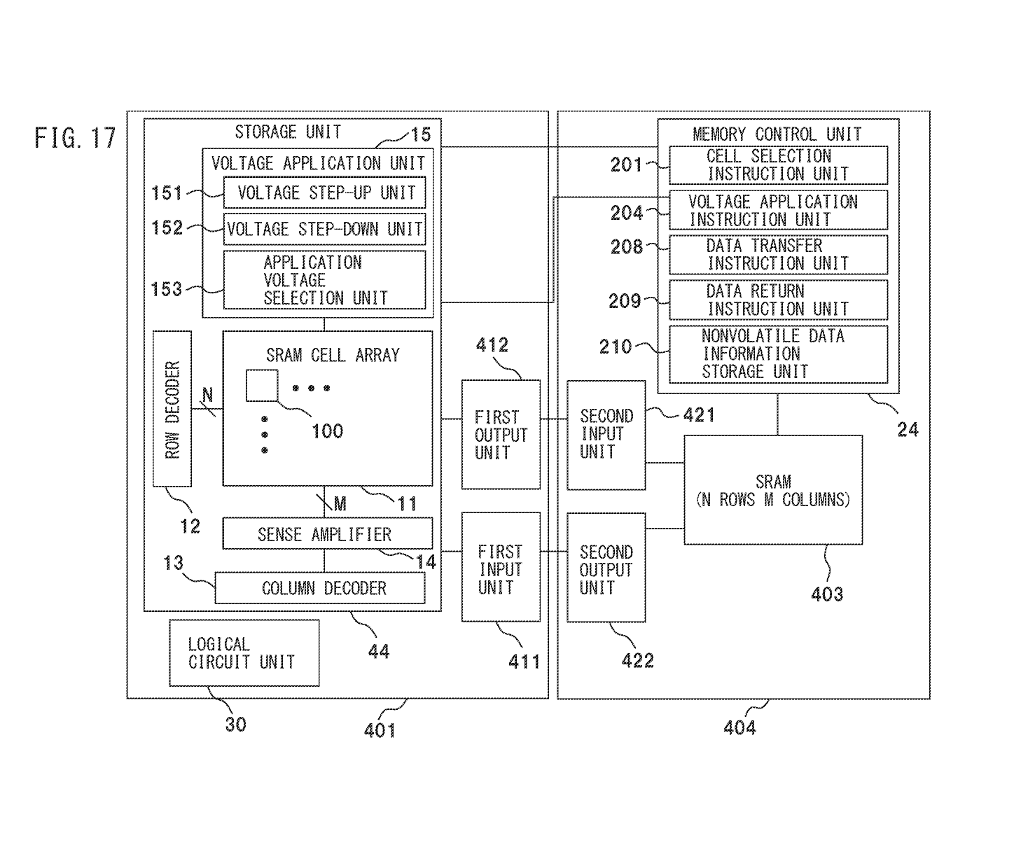

FIG. 17 is a function block diagram of a storage device including a semiconductor device according to a fifth embodiment.

A storage device 5 differs from the storage device 4 in having a second semiconductor device 404 in place of the second semiconductor device 402. The second semiconductor device 404 differs from the second semiconductor device 402 in having a memory control unit 24 in place of the memory control unit 23. Further, the second semiconductor device 404 differs from the second semiconductor device 402 in not having the stored data setting unit 16.

The memory control unit 24 has the cell selection instruction unit 201, the voltage application instruction unit 204, the data transfer instruction unit 208, a data return instruction unit 209, and a nonvolatile data information storage unit 210. The cell selection instruction unit 201, the voltage application instruction unit 204, and the data transfer instruction unit 208 have the same configurations and functions of the cell selection instruction unit 201, the voltage application instruction unit 204, and the data transfer instruction unit 208 of the memory control unit 23.

The data return instruction unit 209 writes the data that is read from each SRAM cell 100 of the SRAM 403 to the SRAM cell 100 located in the corresponding position of the SRAM cell array 11. For example, the data transfer instruction unit 208 writes the data that is read from the SRAM cell 100 located in the first row and the first column of the SRAM 403 to the SRAM cell 100 located in the first row and the first column of the SRAM cell array 11. Further, the data transfer instruction unit 208 writes the data that is read from the SRAM cell 100 located in the Nth row and the Mth column of the SRAM 403 to the SRAM cell 100 located in the Nth row and the Mth column of the SRAM cell array 11.

The nonvolatile data information storage unit 210 stores information indicative of whether the inverted data of the data that is stored in each SRAM cell 100 by the stored data setting unit is used.

In the storage device 5, a processing unit (no illustration) which is mounted on the second semiconductor device 402 determines which of the non-inverted data and the inverted data of the nonvolatile data stored in the SRAM cell 100 is to be used in accordance with the information stored in the nonvolatile data information storage unit 210. In the storage device 5, the processing unit determines which of the non-inverted data and the inverted data of the nonvolatile data stored in the SRAM cell 100 is to be used, and therefore, the stored data setting unit 16 may be omitted.

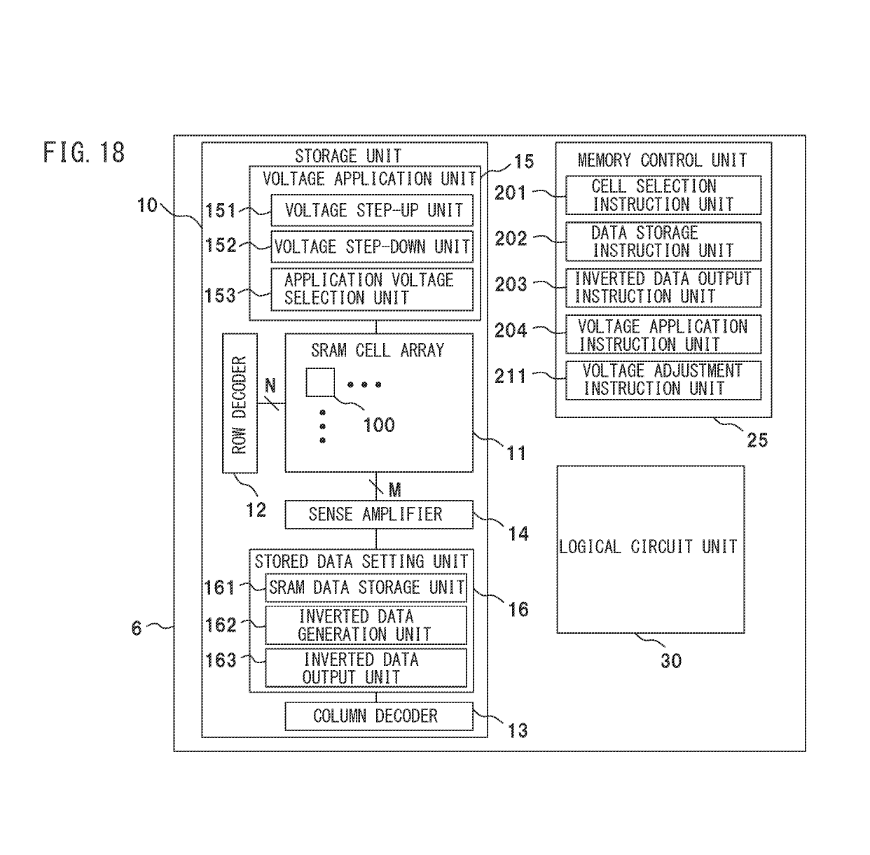

FIG. 18 is a function block diagram of a semiconductor device according to a sixth embodiment.

A semiconductor device 6 differs from the semiconductor device 1 in having a memory control unit 25 in place of the memory control unit 20. The memory control unit 25 differs from the memory control unit 20 in having a voltage adjustment instruction unit 211.

The voltage adjustment instruction unit 211 adjusts a threshold voltage of a MOS transistor forming the latch circuit of the SRAM cell 100 of the SRAM cell array 11 by the voltage characteristics adjustment method explained with reference to FIGS. 1 to 6.

The processing to write and read volatile data to and from, and to store and read nonvolatile data in and from the storage unit 10 of the semiconductor device 6 is performed in the same manner as that of the processing for the storage unit 10 of the semiconductor device 1 explained with reference to FIGS. 10 and 11.

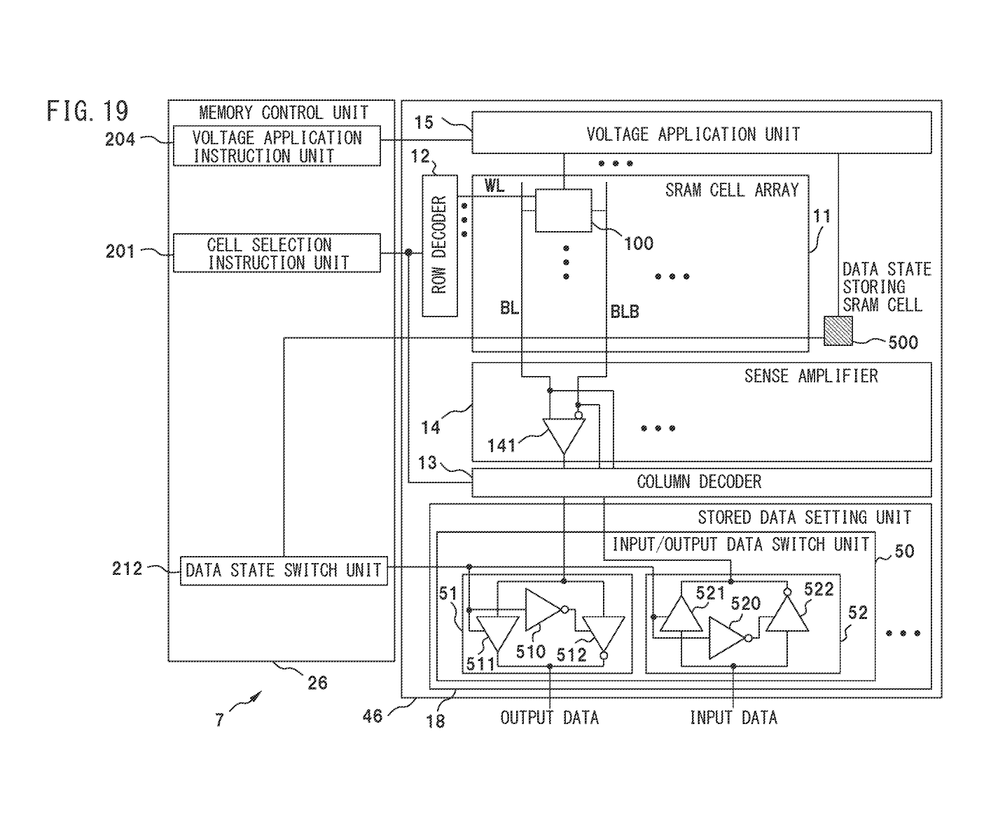

FIG. 19 is a function block diagram of a semiconductor device according to a seventh embodiment.

A semiconductor device 7 differs from the semiconductor device 1 in having a stored data setting unit 18 in place of the stored data setting unit 16. Further, the semiconductor device 7 differs from the semiconductor device 1 in having a memory control unit 26 in place of the memory control unit 20. Furthermore, the semiconductor device 7 differs from the semiconductor device 1 in that a data state storing SRAM cell 500 is arranged in the SRAM cell array 11.

The data state storing SRAM cell 500 is arranged outside the SRAM cell array 11, and therefore, the processing to write and read volatile data in the normal SRAM processing that uses the row decoder 12 and the column decoder 13 is not performed thereon. The data state storing SRAM cell 500 is not used as a storage element for storing data that is input to and output from the storage unit 46, but is used only as an element for storing the state of data that is stored in a plurality of SRAM cells 100. In the initial state of the data state storing SRAM cell 500, nonvolatile data of “0” is stored. When nonvolatile data is stored in a plurality of SRAM cells 100, a high voltage is applied to the data state storing SRAM cell 500 by the voltage application unit 15 and the nonvolatile data that is stored is switched alternately between “0” and “1”.

The stored data setting unit 18 has M input/output data switch units 50 corresponding to the columns of the SRAM cell 100, respectively. Each of the M input/output data switch units 50 has an output data switch unit 51 and an input data switch unit 52.

The output data switch unit 51 has an output switch signal inversion element 510, an output data non-inversion element 511, and an output data inversion element 512. The output switch signal inversion element 510 inputs the inverted signal of the switch signal that is output from the memory control unit 26 to the control terminal of the output data inversion element 512. The switch signal that is output from the memory control unit 26 is input to the control terminal of the output data non-inversion element 511, and the inverted signal of the switch signal that is output from the memory control unit 26 is input to the control terminal of the output data inversion element 512. When the output data non-inversion element 511 is in the enabled state, the output data inversion element 512 enters the disabled state and when the output data non-inversion element 511 is in the disabled state, the output data inversion element 512 enters the enabled state. The output data non-inversion element 511 outputs the data that is output from the corresponding column of the SRAM cell array 11 and the output data inversion element 512 outputs the inverted data of the data that is output from the corresponding column of the SRAM cell array 11.

The input data switch unit 52 has an input switch signal inversion element 520, an input data non-inversion element 521, and an input data inversion element 522. The input switch signal inversion element 520 inputs the inverted signal of the switch signal that is output from the memory control unit 26 to the control terminal of the input data inversion element 522. The switch signal that is output from the memory control unit 26 is input to the control terminal of the input data non-inversion element 521, and the inverted signal of the switch signal that is output from the memory control unit 26 is input to the control terminal of the input data inversion element 522. When the input data non-inversion element 521 is in the enabled state, the input data inversion element 522 enters the disabled state, and when the input data non-inversion element 521 is in the disabled state, the input data inversion element 522 enters the enabled state. The input data non-inversion element 521 outputs the data that is output from the corresponding column of the SRAM cell array 11 and the input data inversion element 522 outputs the inverted data of the data that is output from the corresponding column of the SRAM cell array 11.

Since the same switch signal is input to the output data switch unit 51 and the input data switch unit 52 from the memory control unit 26, when the output data non-inversion element 511 is enabled, the input data non-inversion element 521 becomes enabled. When the output data inversion element 512 is enabled, the input data inversion element 522 becomes enabled. In other words, when the input data switch unit 52 outputs the non-inverted data of the data that is input to the input data switch unit 52 to the SRAM cell 100, the output data switch unit 51 outputs the non-inverted data of the data that is read from the plurality of SRAM cells 100. When the input data switch unit 52 outputs the inverted data of the data that is input to the input data switch unit 52 to the SRAM cell 100, the output data switch unit 51 outputs the non-inverted data of the data that is read from the plurality of SRAM cells 100.

The memory control unit 26 differs from the memory control unit 20 in that a data state switch unit 212 is arranged in place of the data storage instruction unit 202 and the inverted data output instruction unit 203. The data state switch unit 212 switches the states of the data that is input to and output from the plurality of SRAM cells 100 arranged in the SRAM cell array 11 in accordance with the data that is read from the data state storing SRAM cell 500.

The data state switch unit 212 switches the state of the data that is input to and output from the plurality of SRAM cells 100 between the non-inverted data state and the inverted data state in accordance with the data that is read from the data state storing SRAM cell 500. The non-inverted data state is a state where the non-inverted data is written to each of the plurality of SRAM cells 100 and the non-inverted data is read from each of the plurality of SRAM cells 100. The inverted data state is a state where the inverted data is written to each of the plurality of SRAM cells 100 and the inverted data is read from each of the plurality of SRAM cells 100.

The data state switch unit 212 stores nonvolatile data of “0” in the data state storing SRAM cell 500 before the semiconductor device 7 is used, for example, in factory shipment of the semiconductor device 7 etc. Each time nonvolatile data is stored in the plurality of SRAM cells 100, the data state switch unit 212 alternately switches the data state between the non-inverted data state and the inverted data state in response to the switching of the nonvolatile data that is stored in the data state storing SRAM cell 500.

The data state switch unit 212 outputs a switch signal indicating instructions to bring the output data non-inversion element 511 and the input data non-inversion element 521 into the enabled state to the M input/output data switch units 50 when the data state is the non-inverted data state. The data state switch unit 212 outputs a switch signal indicating instructions to bring the output data inversion element 512 and the input data inversion element 522 into the enabled state to the M input/output data switch units 50 when the data state is the inverted data state.

Hereinafter, inputting/outputting of volatile data when the data state is the non-inverted state, inputting/outputting of volatile data when the data state is the inverted state, inputting/outputting of nonvolatile data when the data state is the non-inverted state, and inputting/outputting of nonvolatile data when the data state is the inverted state are explained.

First, inputting/outputting of volatile data when the data state is the non-inverted state in the semiconductor device 7 is explained. When the state of the data that is input and output is the non-inverted state, if “0” is input to the input data switch unit 52 from the outside, the input data switch unit 52 outputs “0” to the SRAM cell 100. The SRAM cell 100 writes “0” as volatile data. When the volatile data that has been written to the SRAM cell 100 is read, the SRAM cell 100 outputs “0” as volatile data to the input data switch unit 52. Since the state of the data that is input and output is the non-inverted state, the input data switch unit 52 outputs “0” that is the non-inverted data of “0” that has been input from the SRAM cell 100 to the outside.

Next, inputting/outputting of volatile data when the data state is the non-inverted state in the semiconductor device 7 is explained. When the state of the data that is input and output is the inverted state, if “0” is input to the input data switch unit 52 from the outside, the input data switch unit 52 outputs “1” to the SRAM cell 100. The SRAM cell 100 writes “1” as volatile data. When the volatile data that has been written to the SRAM cell 100 is read, the SRAM cell 100 outputs “1” as volatile data to the input data switch unit 52. Since the state of the data that is input and output is the inverted state, the input data switch unit 52 outputs “0” that is the inverted data of “1” that has been input from the SRAM cell 100 to the outside.

Next, inputting/outputting of nonvolatile data when the data state is the non-inverted state in the semiconductor device 7 is explained. Since the semiconductor device 7 is in the non-inverted state, “0” is stored as nonvolatile data in the data state storing SRAM cell 500. When the state of data that is input and output is the non-inverted state, if “0” is input to the input data switch unit 52 from the outside, the input data switch unit 52 outputs “0” to the SRAM cell 100. The SRAM cell 100 writes “0” as volatile data. When a high voltage is applied to the SRAM cell 100, “1” that is the inverted data of the volatile data “0” that has been written is stored as nonvolatile data. At this time, a high voltage is also applied to the data state storing SRAM cell 500, and therefore, “1” that is the inverted data of “0” that has been stored as nonvolatile data in the data state storing SRAM cell 500 is stored as nonvolatile data. The data state storing SRAM cell 500 enters the state where “1” is stored as nonvolatile data in the state where “0” can be read as volatile data.

After the power source of the semiconductor device 7 is turned on and off, when the nonvolatile data stored in the SRAM cell 100 is read, “1” that is the data stored as nonvolatile data is read from the data state storing SRAM cell 500. Since “1” is read from the data state storing SRAM cell 500, the state of the data that is input and output enters the inverted state. When the nonvolatile data stored in the SRAM cell 100 is read, the SRAM cell 100 outputs “1” as nonvolatile data to the input data switch unit 52. Since the state of the data that is input and output is the inverted state, the input data switch unit 52 outputs “0” that is the inverted data of “1” that has been input from the SRAM cell 100 to the outside.

Next, inputting/outputting of nonvolatile data when the data state is the inverted state in the semiconductor device 7 is explained. Since the semiconductor device 7 is in the inverted state, “1” is stored as nonvolatile data in the data state storing SRAM cell 500. When the state of the data that is input and output is the inverted state, if “0” is input to the input data switch unit 52 from the outside, the input data switch unit 52 outputs “1” to the SRAM cell 100. The SRAM cell 100 writes “1” as volatile data. When a high voltage is applied to the SRAM cell 100, “0” that is the inverted data of the written volatile data “1” is stored as nonvolatile data. At this time, a high voltage is also applied to the data state storing SRAM cell 500, and therefore, “0” that is the inverted data of “1” that has been stored as nonvolatile data in the data state storing SRAM cell 500 is stored as nonvolatile data. The data state storing SRAM cell 500 enters the state where “0” is stored as nonvolatile data in the state where “1” can be read as volatile data.

After the power source of the semiconductor device 7 is turned on and off, when the nonvolatile data that has been stored in the SRAM cell 100 is read, “0” that is the data stored as nonvolatile data is read from the data state storing SRAM cell 500. Since “0” is read from the data state storing SRAM cell 500, the state of the data that is input and output enters the non-inverted state. When the nonvolatile data that has been stored in the SRAM cell 100 is read, the SRAM cell 100 outputs “0” as nonvolatile data to the input data switch unit 52. Since the state of the data that is input and output is the inverted state, the input data switch unit 52 outputs “0” that is the non-inverted data of “0” that has been input from the SRAM cell 100 to the outside.

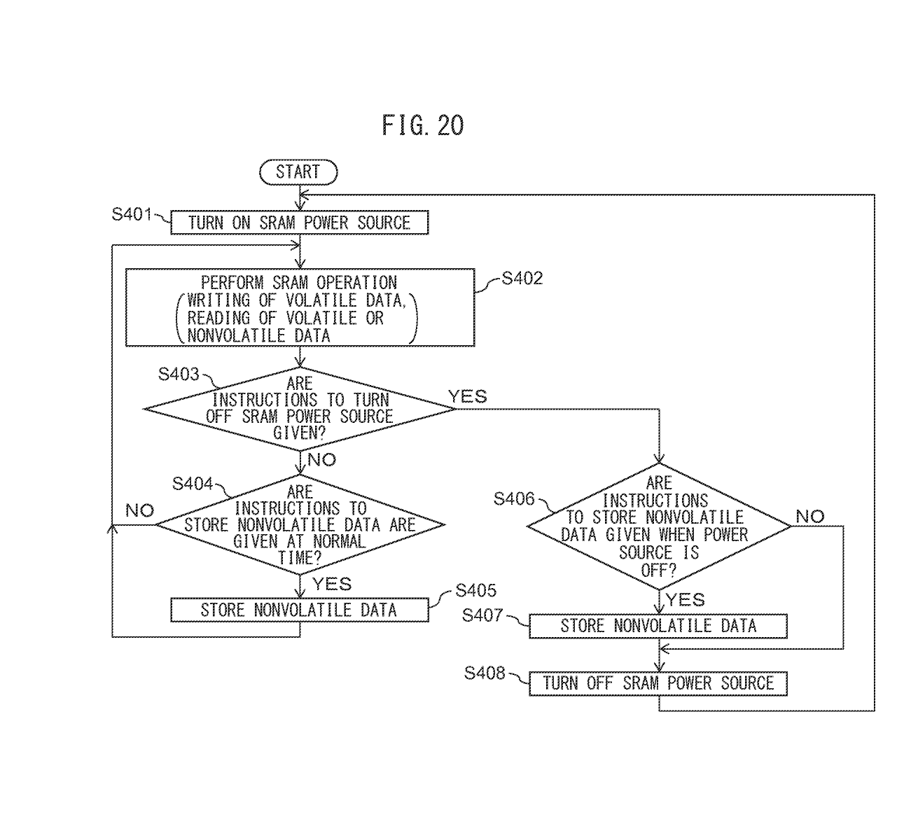

FIG. 20 is a flowchart illustrating a processing flow of processing to write and read volatile data to and from, and to store and read nonvolatile data in and from the SRAM cell 100 that is mounted on the semiconductor device 7.

First, at step S401, the power sources of the plurality of SRAM cells 100 are turned on. Next, at step S402, the normal SRAM operation, i.e., writing and reading of volatile data, is performed on each of the plurality of SRAM cells 100.

The reading at step S402 includes reading of nonvolatile data. Whether the data that has been read to a certain address is nonvolatile data or volatile data depends on the storing of nonvolatile data as step S404, the storing of nonvolatile data at step S407, the turning off of the SRAM power source at step S408, the turning on of the SRAM power source at step S401, or the writing of volatile data to the address at step S402, whichever has been performed the most recent. In other words, when the writing of nonvolatile data at step S404, the storing of nonvolatile data at step S407, the turning off of the SRAM power source at step S408, or the turning on of the SRAM power source at step S401 has been performed the most recent, the nonvolatile data that is stored at step S404 or S407 is read. When the writing of volatile data to the address at step S402 has been performed the most recent, the volatile data that is written by the writing processing is read. Even if the writing of volatile data at step S402 is the most recent action, the writing to an address other than the address is not the writing of volatile data to the above-described address at step S402.

Next, if instructions to turn off the SRAM power source are not given at step S403, the processing proceeds to step S404. If instructions to turn off the SRAM power source are given at step S403, the processing proceeds to step S406.

If the processing proceeds to step S404 and if instructions to store nonvolatile data are not given at the normal time, i.e., when the normal processing is being performed without turning off the SRAM power source, the processing returns to step S402. If instructions to store nonvolatile data are given at the normal time at step S403, the processing proceeds to step S405.

If instructions to turn off the SRAM power source are not given at step S403 and instructions to store nonvolatile data are not given at step S404, each of the plurality of SRAM cells 100 repeats the normal SRAM operation.

When the processing proceeds to step S405, a high voltage is applied to the SRAM without the processing to invert the data written to the SRAM cell 100 being performed and nonvolatile data is stored. Next, the processing returns to step S402.

When instructions to turn off the SRAM power source are given at step S403, the processing proceeds to S406. Next, if instructions to store nonvolatile data are given when the SRAM power source is off at step S406, the processing proceeds to S407. If instructions to store nonvolatile data are not given when the SRAM power source is off at step S406, the processing proceeds to step S408.

When the processing proceeds to step S407, a high voltage is applied to the SRAM cell 100 without the processing to invert the data written to the SRAM being performed and nonvolatile data is stored. Next, the processing proceeds to step S408. When the processing proceeds to step S408, the SRAM power source is turned off. Then, when the power source is turned on again at S401, the nonvolatile data stored in the SRAM cell 100 is read. Next, at step S402, the SRAM cell 100 performs the normal SRAM operation.

As above, the first to seventh embodiments are explained.

In the storage units according to the first to seventh embodiments, nonvolatile data is stored by applying a voltage higher than the rated voltage to the latch circuit of the SRAM cell 100 in the state where the inverted data of the nonvolatile data that is stored in each of the plurality of SRAM cells 100 has been written to each SRAM cell 100. In other words, nonvolatile data is stored by applying a voltage higher than the rated voltage to the latch circuit of the SRAM cell 100 in the state where the inverted data of the nonvolatile data that is read when each of the plurality of SRAM cells 100 functions as a nonvolatile memory cell has been written to each of the plurality of SRAM cells 100. Thus, it is possible to store nonvolatile data at a time by applying a high voltage to the SRAM cells to which the inverted data of the nonvolatile data that is read when each of the plurality of SRAM cells 100 functions as a nonvolatile memory cell has been written.

In the storage units according to the first to seventh embodiments, it is possible to use the SRAM as a nonvolatile memory by storing nonvolatile data in the SRAM cell, and therefore, it is possible to mount a logical circuit that is formed by the CMOS manufacturing process and a nonvolatile memory on a chip without increasing the manufacturing cost. Further, the SRAM cell that is used as a nonvolatile memory also functions as a volatile memory.

Further, in the storage units according to the first to seventh embodiments, it is possible to store the inverted data of the data written to each SRAM cell as nonvolatile data by applying a voltage higher than the rated voltage at a time to the latch circuits of the SRAM cells. Since it is possible to store inverted data as nonvolatile data by applying a voltage higher than the rated voltage at a time to the latch circuits of the SRAM cells, the processing to store nonvolatile data in the SRAM cell is made simpler, and the processing time becomes shorter.

Furthermore, in the storage units according to the first and seventh embodiments, it is possible to store the inverted data of the data written to the SRAM as nonvolatile data, and therefore, it is possible to turn off the power source voltage after storing the data written to the SRAM data as nonvolatile data in desired processing. Then, when the power source voltage is applied next, it is possible to read the data written to the SRAM data as nonvolatile data in desired processing.

In the semiconductor device 2, it is possible to select and store one of the data written to the SRAM cell array 11 and the inverted data of the data as nonvolatile data in accordance with the data written to the SRAM cell whose butterfly curve balance is the worst.

Further, in the semiconductor device 3, when it is determined that the first storage unit 41 no longer functions as a nonvolatile memory, the second storage unit 42 can be used as a nonvolatile memory, and therefore, it is possible to rewrite the data stored as nonvolatile data more times.

Furthermore, in the semiconductor device 6, it is possible to adjust the threshold voltage of the MOS transistor forming the latch circuit of the SRAM cell 100, and therefore, it is possible to compensate for the variations in the threshold voltage of the SRAM cell 100 that is arranged in the SRAM cell array 11.

In the first to seventh embodiments, the SRAM cell 100 that is arranged in the SRAM cell array 11 is used as a nonvolatile memory, but a configuration may be accepted in which only part of the SRAM cells 100 that are arranged in the SRAM cell array are used as nonvolatile memories. For example, a configuration may be accepted in which only the SRAM cells 100 that are arranged in one column of the SRAM cell array 11 are used as nonvolatile memories.

Further, in the first to seventh embodiments, when the power source voltage is supplied to the semiconductor device 1, the application voltage selection unit 153 gradually raises the voltage from 0 V up to the rated voltage by using the voltage of the voltage step-down unit 152 having a voltage division circuit, but a configuration that does not use a voltage division circuit may be adopted. For example, when the rise time of the power source voltage that is supplied to the SRAM cell 100 is sufficiently long compared to the operation speed of the SRAM cell 100, it is possible to read nonvolatile data without using a voltage division circuit.

The semiconductor device according to the present invention may further have a circuit configured to perform processing to detect an error in the read nonvolatile data by the parity check etc. and to perform error correction in accordance with the results of the error detection processing by arranging the SRAM cell 100 for storing redundant data in the SRAM cell array 11.

In the semiconductor device 1, the inverted data generation circuit, such as the inversion element 165 of the inverted data generation unit 162, is arranged in each column of the SRAM cell array 11, but a configuration may be accepted in which one SRAM cell array 11 is arranged in a plurality of columns. In this case, in the stored data setting unit 16, a column selection circuit configured to select one column from among a plurality of columns is further arranged.

In the semiconductor device 1, the data flip-flop 164 stores the data that is written to each SRAM cell 100, but the data flip-flop 164 may store the inverted data of the data that is written to each SRAM cell 100. The data flip-flop 164 may store the inverted data of the data that is written to each SRAM cell 100 by, for example, arranging an inversion element between the data input terminal of the data flip-flop 164 and the output terminal of the amplification element 141.

In the semiconductor device 3, the first storage unit 41 and the second storage unit 42 are each arranged as a memory that is used as a nonvolatile memory, but three or more memories may be mounted. Further, the voltage application unit 15 and the stored data setting unit 16 are arranged in the first storage unit 41 and the second storage unit 42, respectively, but a configuration may be accepted in which nonvolatile data is stored in the two SRAM cell arrays 11 by the single voltage application unit 15 and the single stored data setting unit 16.

The semiconductor device 3 has two storage units, i.e., the first storage unit 41 and the second storage unit 42, but a configuration may be accepted in which the storage unit is formed so as to be mounted on two or more semiconductor devices. The storage devices 4 and 5 are formed by two semiconductor devices, i.e., the first semiconductor device 401 and the second semiconductor device 402 or 404, but the storage device 4 and 5 each may be formed by a single semiconductor device.

In the storage devices 4 and 5, the data that is written to the SRAM cell 100 arranged in the SRAM cell array 11 of the first semiconductor device 401, or the inverted data of the data is stored as nonvolatile data. However, data that is not related to the data that is written to the SRAM cell 100 arranged in the SRAM cell array 11 of the first semiconductor device 401 may be stored as nonvolatile data.

In the first to seventh embodiments, the embodiments in which the SRAM cell 100 functions as a RAM capable of storing nonvolatile data are explained, but the SRAM cell 100 may be used as a cell that functions as a ROM (Read Only Memory).

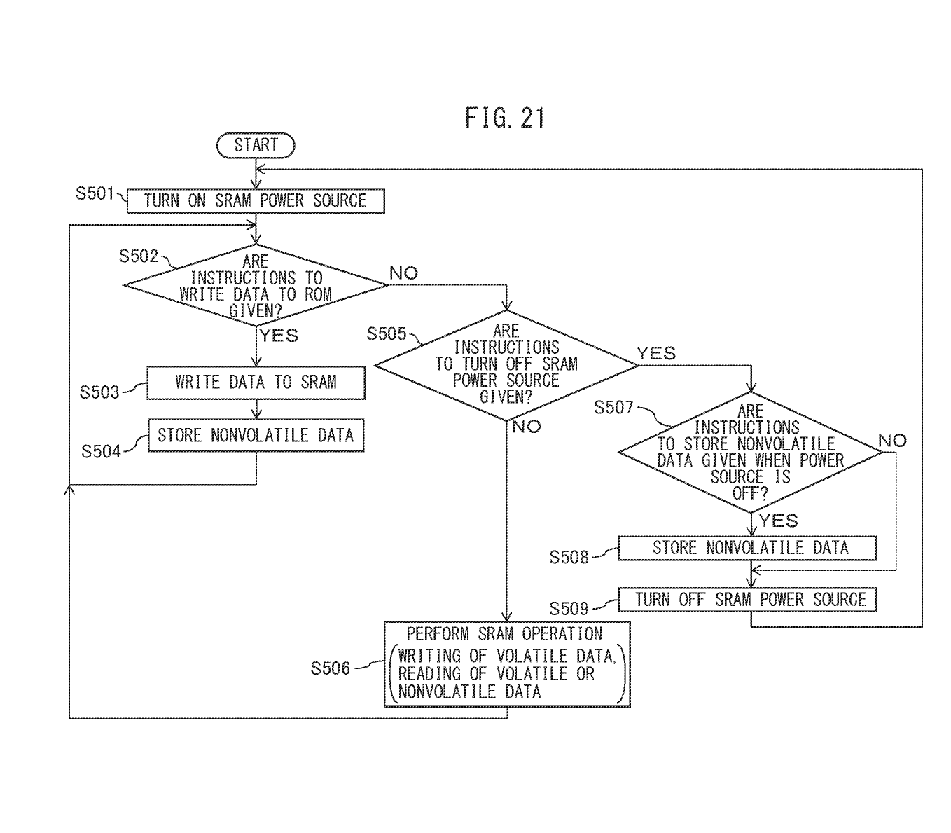

FIG. 21 is a flowchart illustrating a processing flow in which the SRAM cell 100 of the storage unit 10 according to the first embodiment is used as a ROM.

First, at step S501, the power sources of a plurality of SRAM cells 100 are turned on. Next, if instructions to write data to the ROM are given at step S502, the processing proceeds to step S503. If instructions to write data to the ROM are not given at step S502, the processing proceeds to step S505.

When the processing proceeds to step S503, data is written to each of the plurality of SRAM cells 100. Next, at step S504, the processing explained with reference to FIG. 10 is performed and thereby nonvolatile data is stored. Next, the data that was inverted when the nonvolatile data was stored is inverted again. Next, the processing returns to step S502.

When the processing proceeds to step S505 but instructions to turn off the SRAM power source are not given, the processing proceeds to step S506 and after the normal SRAM operation is performed, the processing returns to step S502. When instructions to turn off the SRAM power source are given at step S505, the processing proceeds to step S507.

If the processing proceeds to step S507 and instructions to store nonvolatile data are given when the SRAM power source is off, the processing proceeds to step S508. If instructions to store nonvolatile data are not given when the SRAM power source is off at step S507, the processing proceeds to step S509.

When the processing proceeds to step S508, the processing explained with reference to FIG. 10 is performed and thereby the nonvolatile data is stored. Next, the processing proceeds to step S509. When the processing proceeds to step S509, the SRAM power source is turned off. Then, when the power source is turned on again at S501, the nonvolatile data that is stored in the SRAM cell 100 is retained as data that can be rewritten by the SRAM operation. Next, at S502, whether instructions to write data to the ROM are given to the SRAM cell 100 is determined.

As explained above, the SRAM according to the present invention may store nonvolatile data as well as to operate as a normal SRAM. The SRAM cell according to the present invention may store desired data as nonvolatile data in factory shipment. For example, it is possible to reduce the rise time of a device on which the SRAM cell according to the present invention is mounted by storing data, such as computer programs, that is used in predetermined processing in each SRAM cell according to the present invention.

Further, it is possible to read the stored nonvolatile data when the SRAM power source is turned on after it has been turned off by storing the data that is written as volatile data to the SRAM cell according to the present invention as nonvolatile data.

Furthermore, it is possible to use the SRAM cell according to the present invention as a ROM. Since the SRAM cell according to the present invention can be manufactured by the same process as the manufacturing process of the normal SRAM cell that can be manufactured by the same manufacturing process as that of the CMOS, it is possible to implement the function of the ROM by the same manufacturing process as the manufacturing process of the CMOS that is used to form a logical circuit.

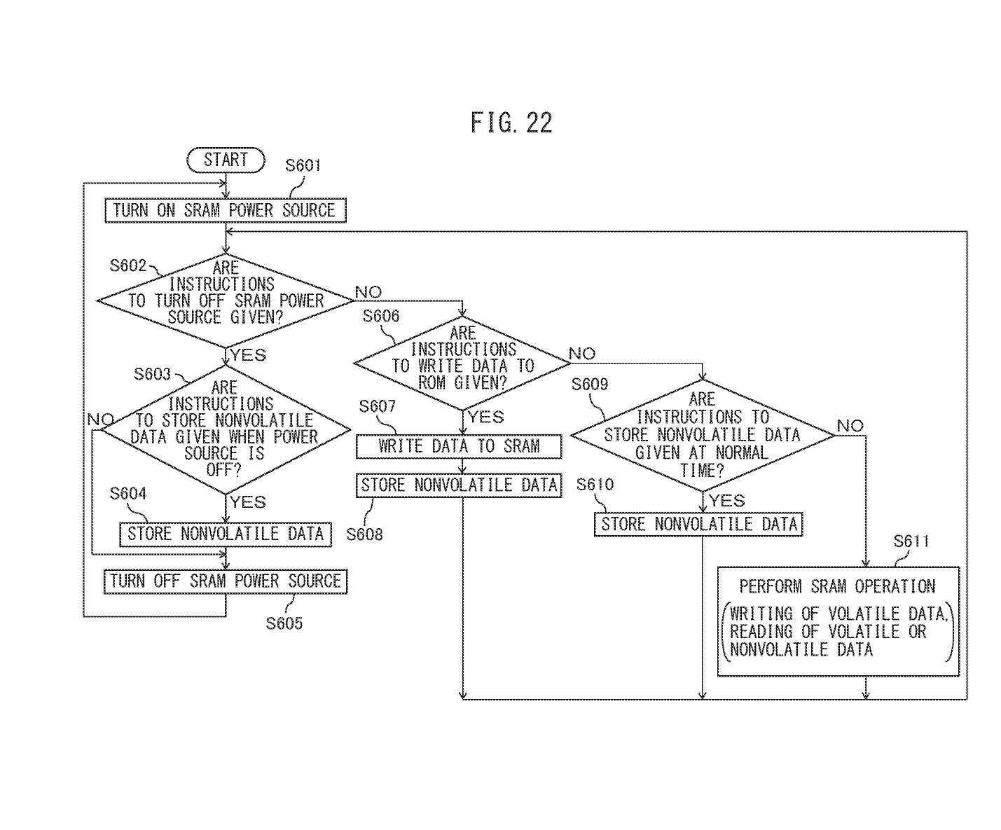

FIG. 22 is a flowchart comprehensively illustrating processing that can use the SRAM according to the present invention.

First, at step S601, the power sources of a plurality of SRAM cells 100 are turned on. Next, if instructions to turn off the SRAM power source are given at step S602, the processing proceeds to step S603. If instructions to turn off the SRAM power source are not given at step S602, the processing proceeds to step S606.

If instructions to store nonvolatile data are given when the SRAM power source is off at step S603, the processing proceeds to step S603. If instructions to store nonvolatile data are not given when the SRAM power source is off at step S603, the processing proceeds to step S605.

When the processing proceeds to step S604, nonvolatile data is stored. Next, the processing proceeds to step S605. When the processing proceeds to step S605, the SRAM power source is turned off. Then, when the power source is turned on again at step S601, the nonvolatile data stored in the SRAM cell 100 is retained as data that can be rewritten by the SRAM operation. Next, whether instructions to turn off the SRAM power source are given is determined at step S602.

If the processing proceeds to step S606 and instructions to write data to the ROM are given, the processing proceeds to step S607. If instructions to write data to the ROM are not given at step S606, the processing proceeds to step S609. When the processing proceeds to step S607, data is written to each of the plurality of SRAM cells 100. The data that is written to each of the plurality of SRAM cells 100 may be inverted outside the semiconductor device in accordance with the embodiments or may be inverted when the stored nonvolatile data is read. Next, nonvolatile data is stored at step S608. Next, the processing returns to step S602.

If the processing proceeds to step S609 and instructions to store nonvolatile data are given at the normal time, the processing proceeds to step S610. If instructions to store nonvolatile data are not given at the normal time at step S609, the processing proceeds to step S611. When the processing proceeds to step S610, nonvolatile data is stored. Next, the processing returns to step S602. When the processing proceeds to step S611, the normal SRAM operation is performed. Next, the processing returns to step S602.

In the first to fourth embodiments and in the sixth embodiment, in the processing to store nonvolatile data in the SRAM cell 100, nonvolatile data is stored in the state where the inverted data of the data that is stored as nonvolatile data has been written to the SRAM cell 100. However, it may also be possible to adopt a configuration in which the nonvolatile data that is stored as the inverted data of the data that has been written to the SRAM cell is inverted when the nonvolatile data is read so that the read data is consistent with the written data.

In the fifth embodiment, whether the inverted data of the data that is stored as nonvolatile data in the SRAM cell 100 is used or the non-inverted data of the data that is stored as nonvolatile data in the SRAM cell 100 is used is determined when the nonvolatile data is read.

In the seventh embodiment, the data written to the SRAM cell 100 is read as nonvolatile data without inverting the data by using the data state storing SRAM in which the data that is stored is inverted by the application of a high voltage when the nonvolatile data is stored.

When the SRAM cell according to the present invention is used as a ROM, nonvolatile data may be stored by applying a high voltage to the SRAM cell after writing the inverted data of the data written to the SRAM cell. Further, nonvolatile data may be stored by applying a high voltage to the SRAM cell in the state where data has been written to the SRAM cell and then to invert the read data when the nonvolatile data is read.

What is claimed is:

1. A semiconductor device comprising:
a plurality of storage elements each having a plurality of MOS transistors forming a latch circuit;
a stored data setting unit configured to write inverted data of nonvolatile data that is read when each of the plurality of storage elements functions as a nonvolatile memory cell to each of the plurality of storage elements; and
a voltage application unit configured to store the nonvolatile data in each of the plurality of storage elements by applying a predetermined high voltage higher than a power source voltage applied during normal latch operation to each of the latch circuits.

2. The semiconductor device according to claim 1, wherein
each of the plurality of storage elements has:
a first switch for turning on and off the connection between the latch circuit and a first data line; and
a second switch for turning on and off the connection between the latch circuit and a second data line to and from which inverted data of data that is input to and output from the first data line is input and output, and
the first switch turns off the connection between the latch circuit and the first data line and the second switch turns off the connection between the latch circuit and the second data line when the voltage application unit applies the predetermined high voltage.

3. The semiconductor device according to claim 2, wherein
each of the plurality of storage elements has a pair of NMOS transistors whose sources are grounded and a pair of PMOS transistors whose sources are connected to the voltage application unit, both forming the latch circuit,
the first switch is a MOS transistor whose gate is connected to a word line, whose source is connected to the first data line, and whose drain is connected to the drains of one of the pair of NMOS transistors and one of the pair of PMOS transistors, and to the gates of the other of the pair of NMOS transistors and the other of the pair of PMOS transistors, and
the second switch is a MOS transistor whose gate is connected to the word line, whose source is connected to the second data line, and whose drain is connected to the drains of the other of the pair of NMOS transistors and the other of the pair of PMOS transistors, and to the gates of the one of the pair of NMOS transistors and the one of the pair of PMOS transistors.

4. The semiconductor device according to claim 1, wherein
the voltage application unit applies the predetermined high voltage at a time to each of the latch circuits.

5. The semiconductor device according to claim 1, wherein
each of the plurality of storage elements is used as volatile memory cell.

6. The semiconductor device according to claim 1, wherein
the stored data setting unit has:
a data storage unit configured to store the nonvolatile data; and
an inverted data output unit configured to output inverted data of the nonvolatile data to each of the plurality of storage elements.

7. The semiconductor device according to claim 1, wherein
the stored data setting unit has:
a data storage unit configured to store inverted data of the nonvolatile data; and
an inverted data output unit configured to output data that is stored in the data storage unit to each of the plurality of storage elements.

8. The semiconductor device according to claim 1, wherein
the stored data setting unit has a nonvolatile data input unit to which the nonvolatile data or inverted data of the nonvolatile data is input from the outside.

9. The semiconductor device according to claim 8, wherein
the stored data setting unit further has a nonvolatile data output unit configured to output the nonvolatile data or inverted data of the nonvolatile data to the outside.

10. The semiconductor device according to claim 1, wherein
the stored data setting unit has a data state switch unit configured to alternately switch the data state between: a non-inverted data state where non-inverted data is written to each of the plurality of storage elements and non-inverted data of data that has been written to each of the plurality of storage elements is read; and an inverted data state where inverted data is written to each of the plurality of storage elements and inverted data of data that has been written to each of the plurality of storage elements is read, each time the nonvolatile data is stored to each of the plurality of storage elements.

11. The semiconductor device according to claim 1, wherein
the voltage application unit reads the nonvolatile data by applying a voltage lower than a power source voltage applied during normal latch operation to the latch circuit as a power source voltage before applying a power source voltage to the latch circuit.

12. The semiconductor device according to claim 1, further comprising a nonvolatile data information storage unit configured to store information indicative of the state of data written to each of the plurality of storage elements by the stored data setting unit.

13. The semiconductor device according to claim 12, wherein
information that is stored by the nonvolatile data information storage unit is information indicative of whether inverted data of data that is stored in each of the plurality of storage elements by the stored data setting unit is used.

14. A storage device comprising:
a storage unit having a plurality of storage elements each having a plurality of MOS transistors forming a latch circuit; and
a control unit configured to write inverted data of nonvolatile data that is read when each of the plurality of storage elements functions as a nonvolatile memory cell to each of the plurality of storage elements, and to store the nonvolatile data in each of the plurality of storage elements by applying a predetermined high voltage higher than a power source voltage applied during normal latch operation to each of the latch circuits.

15. The storage device according to claim 14, wherein
the control unit applies the predetermined high voltage at a time to each of the latch circuits.

16. The storage device according to claim 14, wherein
each of the plurality of storage elements is used as a volatile memory cell.

17. A storage device comprising:
a first storage unit having a plurality of storage elements each having a plurality of MOS transistors forming a latch circuit;
a second storage unit having a plurality of storage elements each having a plurality of MOS transistors forming a latch circuit; and
a control unit configured to:
write inverted data of nonvolatile data that is read when each of the plurality of storage elements possessed by the first storage unit or the second storage unit functions as a nonvolatile memory cell to each of the plurality of storage elements possessed by the first storage unit or the second storage unit;
store nonvolatile data in the first storage unit or the second storage unit by applying a predetermined high voltage higher than a power source voltage applied during normal latch operation to each of the latch circuits in which the inverted data is stored;
determine whether or not the first storage unit functions as a nonvolatile memory; and
use the second storage memory as a nonvolatile memory in place of the first storage unit when determining that the first storage unit does not function as a nonvolatile memory.

18. The storage device according to claim 17, wherein
the control unit:
counts the number of times data is written to the first storage unit as a nonvolatile memory; and
determines that the first storage unit no longer functions as a v nonvolatile memory when the counted number of times exceeds a predetermined threshold value.

19. A method for controlling a storage device having a plurality of storage elements each having a plurality of MOS transistors forming a latch circuit, the method comprising:
writing inverted data of nonvolatile data that is read when each of the plurality of storage elements functions as a nonvolatile memory to each of the plurality of storage elements; and
storing the nonvolatile data in each of the plurality of storage elements by applying a predetermined high voltage higher than a power source voltage applied during normal latch operation to each of the latch circuits in which the inverted data is stored.

20. The method according to claim 19, wherein
the predetermined high voltage is applied at a time when the nonvolatile data is stored in each of the plurality of storage elements.

21. The method according to claim 19, further comprising reading the nonvolatile data by raising a power source voltage from a voltage lower than a power source voltage during normal latch operation when applying a power source voltage to the latch circuit.

22. The method according to claim 19, wherein
processing to detect an error of the read nonvolatile data is performed, and
error correction processing is performed on the read nonvolatile data in accordance with the results of the error detection processing.

23. The method according to claim 19, further comprising:
applying a voltage lower than a power source voltage during normal latch operation to the latch circuit as a power source voltage; and
applying a voltage higher than a power source voltage during normal latch operation to the latch circuit as a power source voltage, after applying the lower voltage.

24. The method according to claim 19, wherein
each of the plurality of storage elements is used as a volatile memory.
